(19) United States
(12) Patent Application Publication
(10) Pub. No.: US 2008/0121999 A1
(43) Pub. Date: May 29, 2008

(54) SEMICONDUCTOR DEVICE WHICH HAS MOS STRUCTURE AND METHOD OF MANUFACTURING THE SAME

(75) Inventors: Takaaki KAWAHARA, Tokyo (JP); Shinsuke Sakashita, Tokyo (JP); Jiro Yugami, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Renesas Technology Corp., Chiyoda-ku (JP)

(21) Appl. No.: 11/772,624

(22) Filed: Jul. 2, 2007

(30) Foreign Application Priority Data
Jul. 4, 2006 (JP) 2006-184347

(51) Int. Cl. H01L 29/78; H01L 21/04

(52) U.S. Cl. 257/366; 438/594; 257/E29.264; 257/E21.04

(57) ABSTRACT

The present invention offers the semiconductor device which can solve each problem, such as Fermi level pinning, formation of gate electrode depletion, and a diffusion phenomenon, can adopt a material suitable for each gate electrode of the MOS structure from which threshold voltage differs, and can adjust (control) threshold voltage appropriately by the manufacturing process simplified more and which has a MOS structure.

In the semiconductor device which has a MOS structure concerning the present invention, a PMOS transistor has the structure in which the gate insulating film, first metal layer, second metal layer, and polysilicon layer was formed in the order concerned. An NMOS transistor has the structure by which a gate insulating film and polysilicon were formed in the order concerned.

### CROSS-REFERENCE TO RELATED APPLICATION

The present application claims priority from Japanese patent application No. 2006-184347 filed on Jul. 4, 2006, the content of which is hereby incorporated by reference into this application.

### 1. FIELD OF THE INVENTION

This invention is an invention concerning semiconductor device which has a MOS structure and method of manufacturing the same, for example, can be applied to the gate electrode structure of a plurality of MOS electric field type transistors from which threshold voltage differs.

### 2. DESCRIPTION OF THE BACKGROUND ART

In order to improve the integration density of a semiconductor device and to improve performance, the microfabrication of the semiconductor device is progressing. The analyses which use the high dielectric constant material called a high-k film as a gate insulating film of an MOS transistor as construction material of a semiconductor device are also performed briskly. When a high-k film is applicable as a gate insulating film, even if it makes physical thickness of a gate insulating film to some extent thick, electric silicon oxide film conversion thickness will become thin. A physically and structurally stable gate insulating film can be realized, and gate leakage current can be reduced from a conventional silicon oxide film.

However, when a high-k film (for example, HfSiON) was used as a gate insulating film, the problem that the threshold voltage (Vₜₕ) of a PMOS transistor became very high, and ON-state current became small especially compared with the case where oxynitriding silicon (SiON) is used occurred. It is reported as for this, for the phenomenon of Fermi level pinning (Fermi Level Pinning) to happen, when a high-k film is used as a gate insulating film and polycrystalline silicon is used as a gate electrode (Nonpatent Literature 1). It is thought that Fermi level pinning is generated by forming the level based on combination of the metal which forms a high-k film, and silicon, at the neighborhood of the gate insulating film side interface in a gate electrode.

When the electric field applied to a gate electrode becomes strong relatively with the thickness reduction of a gate insulating film, the phenomenon in which a depletion layer is formed in a gate electrode will occur. Under the influence of such a depletion layer, even if it applies gate voltage to a gate electrode, electric field sufficient for a gate insulating film is not applied in any case of a high-k film and a SiON film, but it becomes difficult to induce a carrier in a channel region.

In order to raise the conductivity of polycrystalline silicon, when the impurity quantity mixed in the polycrystalline silicon film concerned is made to increase, this impurity is diffused to the channel region of a semiconductor over a gate insulating film, and an electrical property may be fluctuated. In a PMOS transistor, although boron may be adopted as the impurity concerned, the above-mentioned diffusion phenomenon becomes remarkable in this case.

In order to solve each problem, such as Fermi level pinning, formation of gate electrode depletion, a diffusion phenomenon, etc. which are generated in the above-mentioned PMOS transistor, the adoption of the metal gate which forms a gate electrode with a metallic material is considered. Unlike polycrystalline silicon, the metal cannot change a work function a lot by adjusting impurity concentration. For this reason, in order to change the threshold value of a metal gate electrode, it is necessary to change the kind of metal which forms this electrode.

For example, Hf, Zr, Al, Ti, Ta, Mo, etc. are reported to the metallic material suitable for the gate electrode of NMOS which has a work function of 4.3 or less eV. As for the metallic material suitable for the gate electrode of PMOS which has a work function of 4.8 or more eV, tungsten nitride (WN), nickel (Ni), rhenium (Re), iridium (Ir), platinum (Pt), ruthenium oxide (RuO₂), iridium oxide (IrO₂), molybdenum nitride (MoN), etc. are reported.

Investigation which uses titanium nitride (TiN) as a metal gate electrode material is also advanced. However, as for TiN formed by the conventional sputtering technique, since the work function is set to about 4.6 eV (near the mid gap of silicon, i.e. near the mean value of energy Ec of the lower end of a conduction band, and energy Ev of the upper end of a valence band of a silicon substrate), in an NMOS transistor and a PMOS transistor, threshold voltage (Vₜₕ) becomes high. However, by forming the TiN film concerned at the low temperature less than 450° C. with the thermal CVD method using a titanium tetrachloride (TiCl₄) and ammonia (NH₃), the damage to a gate insulating film can be suppressed, and gate leakage current can be reduced, and the work function of 4.8 or more eV suitable for a PMOS transistor can be acquired (Nonpatent Literature 2).

The method of implanting fluorine (F) into a substrate in PMOS, and implanting nitrogen (N₂) into a substrate in an NMOS transistor is proposed as a controlling method of threshold voltage (Vₜₕ) (Nonpatent Literature 3). It is thought that for example, the threshold voltage (Vₜₕ) which became high can be dropped since fluorine fills the hole formed of the reaction between a high-k film and silicon when fluorine (F) is implanted into a silicon substrate in a PMOS transistor. However, when there is too much implantation amount of the fluorine concerned, it will become a cause of an interface state conversely and transistor characteristics will deteriorate. Therefore, adjustment of delicate fluorine implantation amount to a substrate is needed for control of threshold voltage (Vₜₕ).

[Nonpatent Literature 1] C. Hobbs et al and “Fermi Level Pinning at the PolySi/Metal Oxide Interface”, 2003 Symposium on VLSI Technology Digest of Technical Papers, pp 9

[Nonpatent Literature 2] S. Sakashita and K. Mori, K. Tanaka and M. Mizutani, M. Inoue and S. Yamanari, J. Yugami and H. Miyatake, and M. Yoneda, “Low temperature divided CVD technique for TiN metal gate electrodes of p-MISFETs”, Ext. Abstr. Solid State Devices and Materials, 2005, pp 854-855

[Nonpatent Literature 3] M. Inoue and S. Tsujikawa, M. Mizutani and K. Nomura, T. Hayashi and KShiga, J. Yugami and J. Tsuichimoto, Y. Ohno and M. Yoneda, “Fluorine Incorporation into HfSiON Dielectric for Vₜₕ Control and Its Impact on Reliability for Poly-Si Gate pFET”, IEDM Tech. Dig., 2005, pp 425-428

### SUMMARY OF THE INVENTION

As mentioned above, when a high-k film is applied to a gate insulating film, adopting a metallic material as a gate electrode is examined. When a CMOS transistor is formed especially from this technique, a problem occurs. The CMOS transistor is provided with both the PMOS transistor and the NMOS transistor, and must use for each gate electrode the metallic material which has a suitable work function. This is based on the need of adjusting the threshold voltage of a PMOS transistor and an NMOS transistor, as mentioned above, but the manufacturing process will be very complicated in a conventional device manufacturing method. Therefore, to simplify a manufacturing process if possible is desired.

Then, the present invention aims at offering the semiconductor device which has a MOS structure, and its manufacturing method which can solve each problem, such as Fermi level pinning, above-mentioned formation of gate electrode depletion, an above-mentioned diffusion phenomenon, etc., and which can adopt a material suitable for each gate electrode of a MOS structure with which threshold voltage differs, and can adjust (control) threshold voltage appropriately by the manufacturing process simplified more.

In order to attain the above-mentioned purpose, a semiconductor device which has a MOS structure according to claim 1 concerning the present invention comprises a first and a second semiconductor layer, a first gate insulating film arranged over the first semiconductor layer, a first gate electrode which has a first metal layer arranged over the first gate insulating film, a second metal layer arranged over the first metal layer, and a third semiconductor layer arranged over the second metal layer, a second gate insulating film arranged over the second semiconductor layer, and a second gate electrode which has a fourth semiconductor layer arranged over the second gate insulating film.

A method of manufacturing a semiconductor device which has a MOS structure according to claim 8 concerning the present invention comprises the steps of (a) forming a gate insulating film over a first semiconductor layer and a second semiconductor layer, (b) forming a first metal layer over the gate insulating film, (c) forming a second metal layer over the first metal layer, (d) leaving the first metal layer and the second metal layer above the first semiconductor layer, and removing the first metal layer and the second metal layer from an upper part of the second semiconductor layer, (e) forming a semiconductor layer for gate electrodes over the second metal layer and the second semiconductor layer, and (f) forming a first gate electrode above the first semiconductor layer, and forming a second gate electrode above the second semiconductor layer by patterning the first metal layer, the second metal layer, and the semiconductor layer for gate electrodes.

A semiconductor device which has a MOS structure according to claim 15 concerning the present invention comprises a first and a second semiconductor layer, a first gate insulating film arranged over the first semiconductor layer, a first gate electrode which has a first metal layer arranged over the first gate insulating film, a second metal layer arranged over the first metal layer, a third metal layer arranged over the second metal layer, and a third semiconductor layer arranged over the third metal layer, a second gate insulating film arranged over the second semiconductor layer; and a second gate electrode which has a fourth metal layer arranged over the second gate insulating film, a fifth metal layer arranged over the fourth metal layer, and a fourth semiconductor layer arranged over the fifth metal layer, wherein the second metal layer and the fourth metal layer are layers of the same material and thickness, and the third metal layer and the fifth metal layer are layers of the same material and thickness.

A method of manufacturing a semiconductor device which has a MOS structure according to claim 22 concerning the present invention comprises the steps of (a) forming a gate insulating film over a first semiconductor layer and a second semiconductor layer, (b) forming a metal layer of a 1st layer over the gate insulating film, (c) leaving the metal layer of the 1st layer above the first semiconductor layer, and removing the metal layer of the 1st layer from an upper part of the second semiconductor layer, (d) forming a metal layer of a 2nd layer over the metal layer of the 1st layer, and the second semiconductor layer, (e) forming a metal layer of a 3rd layer over the metal layer of the 2nd layer, (f) forming a semiconductor layer for gate electrodes over the metal layer of the 3rd layer, and (g) patterning the metal layer of the 1st layer, the metal layer of the 2nd layer, the metal layer of the 3rd layer, and the semiconductor layer for gate electrodes, forming a first gate electrode in the first semiconductor layer upper part, and forming a second gate electrode above the second semiconductor layer.

A semiconductor device which has a MOS structure according to claim 29 concerning the present invention comprises a first semiconductor layer which contained halogen in a front surface, a second semiconductor layer which contained nitrogen in a front surface, a first gate insulating film arranged over the first semiconductor layer, a first gate electrode which has a first metal layer arranged over the first gate insulating film, and a third semiconductor layer arranged over the first metal layer, a second gate insulating film arranged over the second semiconductor layer, and a second gate electrode which has a second metal layer arranged over the second gate insulating film, and a fourth semiconductor layer arranged over the second metal layer, wherein the first metal layer and the second metal layer are layers of the same material and thickness.

A method of manufacturing a semiconductor device which has a MOS structure according to claim 31 concerning the present invention comprises the steps of (a) implanting halogen into a front surface of a first semiconductor layer, (b) implanting nitrogen into a front surface of a second semiconductor layer, (c) forming a gate insulating film over the first semiconductor layer and the second semiconductor layer, (d) forming a metal layer over the gate insulating film, (e) forming a semiconductor layer for gate electrodes over the metal layer, and (f) patterning the metal layer and the semiconductor layer for gate electrodes, forming a first gate electrode above the first semiconductor layer, and forming a second gate electrode above the second semiconductor layer.

A semiconductor device which has a MOS structure according to claim 1 concerning the present invention comprises a first and a second semiconductor layer, a first gate insulating film arranged over the first semiconductor layer, a first gate electrode which has a first metal layer arranged over the first gate insulating film, a second metal layer arranged over the first metal layer, and a third semiconductor layer arranged over the second metal layer, a second gate insulating film arranged over the second semiconductor layer, and a second gate electrode which has a fourth semiconductor layer arranged over the second gate insulating film.

Therefore, in the first MOS structure that has a first gate electrode, since it has the first metal layer etc., Fermi level pinning, depletion-ization in a gate electrode, etc. are solvable. By the first MOS structure, threshold voltage is selected by a first metal layer, a second metal layer, and the third semiconductor layer to threshold voltage being selected by only the fourth semiconductor layer as for the second MOS structure that has a second gate electrode. That is, in the first MOS structure, more accurate (fine) adjustment of threshold voltage can be performed. In a first gate electrode, the first metal layer directly arranged on a first gate insulating film can be selected, for example from a viewpoint of the proper work function of the first MOS structure. On the other hand, a second metal layer can be selected, for example from a viewpoint of suppression of the diffusion of a substance from a third semiconductor layer. That is, since the metal layer which specialized in each use is formed independently separately, simplification of a manufacturing process can be aimed at rather than the case where the metal layer which has each use is formed. The impurity introduced into a third semiconductor layer may come to be which conductivity type by existence of a first metal layer etc. Therefore, the same conductivity type impurity can be introduced into a third semiconductor layer and a fourth semiconductor layer, and simplification of a manufacturing process can be aimed at also in this point. Thickness of a first metal layer and a second metal layer can be made thin by adopting a third semiconductor layer in a first gate electrode. Hereby, when patterning a third semiconductor layer and a fourth semiconductor layer, a first metal layer and a second metal layer can also be patterned collectively, and simplification of a manufacturing process can be aimed at also in this point.

A method of manufacturing a semiconductor device which has a MOS structure according to claim 8 concerning the present invention comprises the steps of (a) forming a gate insulating film over a first semiconductor layer and a second semiconductor layer, (b) forming a first metal layer over the gate insulating film, (c) forming a second metal layer over the first metal layer, (d) leaving the first metal layer and the second metal layer above the first semiconductor layer, and removing the first metal layer and the second metal layer from an upper part of the second semiconductor layer, (e) forming a semiconductor layer for gate electrodes over the second metal layer and the second semiconductor layer, and (f) forming a first gate electrode above the first semiconductor layer, and forming a second gate electrode above the second semiconductor layer by patterning the first metal layer, the second metal layer, and the semiconductor layer for gate electrodes.

Therefore, the semiconductor device according to claim 1 which has an MOS structure can be manufactured. In the first MOS structure that has a first gate electrode especially, Fermi level pinning, depletion-ization of a gate electrode, etc. are solvable. It can be set as the same conductivity type as a fourth semiconductor layer as a third semiconductor layer, and a manufacturing process can be simplified. Thickness of each metal layer can be made thin by adopting a third semiconductor layer in a first gate electrode. Hereby, when patterning a third semiconductor layer and a fourth semiconductor layer, the first and a second metal layer can also be patterned collectively, and manufacture becomes easy.

A semiconductor device which has a MOS structure according to claim 15 concerning the present invention comprises a first and a second semiconductor layer, a first gate insulating film arranged over the first semiconductor layer, a first gate electrode which has a first metal layer arranged over the first gate insulating film, a second metal layer arranged over the first metal layer, a third metal layer arranged over the second metal layer, and a third semiconductor layer arranged over the third metal layer, a second gate insulating film arranged over the second semiconductor layer; and a second gate electrode which has a fourth metal layer arranged over the second gate insulating film, a fifth metal layer arranged over the fourth metal layer, and a fourth semiconductor layer arranged over the fifth metal layer, wherein the second metal layer and the fourth metal layer are layers of the same material and thickness, and the third metal layer and the fifth metal layer are layers of the same material and thickness.

Therefore, in the second MOS structure that has a second gate electrode, since the fourth metal layer and the fifth metal layer are arranged, even if a second gate insulating film reduces thickness, it can prevent that a depletion layer is formed in the second gate electrode concerned. In the first MOS structure that has a first gate electrode, since it has the first metal layer etc., Fermi level pinning, depletion-ization in a gate electrode, etc. are solvable. Threshold voltage is selected by a first metal layer, a second metal layer, a third metal layer, and the third semiconductor layer in the first MOS structure. On the other hand, as for the second MOS structure, threshold voltage is selected by a fourth metal layer, a fifth metal layer, and the fourth semiconductor layer. That is, in the part whose number of layers of the metal layer increased, as for the first and the second MOS structure, more accurate (fine) adjustment of threshold voltage can be performed. In a first gate electrode, the first metal layer directly arranged on a first gate insulating film can be selected, for example from a viewpoint of the proper work function of the first MOS structure. On the other hand, a third metal layer can be selected, for example from a viewpoint of suppression of the diffusion of a substance from a third semiconductor layer. In a second gate electrode, the fourth metal layer directly arranged on a second gate insulating film can be selected, for example from a viewpoint of the proper work function of the second MOS structure. That is, since the metal layer which specialized in each use is formed independently separately, simplification of a manufacturing process can be aimed at rather than the case where the metal layer which has each use is formed. The impurity introduced into the third and the fourth semiconductor layer may come to be which conductivity type by existence of each metal layer. Therefore, the same conductivity type impurity can be introduced into a third semiconductor layer and a fourth semiconductor layer, and simplification of a manufacturing process can be aimed at also in this point. Thickness of the first, the second, and the third metal layer can be made thin by adopting a third semiconductor layer in a first gate electrode. In a second gate electrode, thickness of the fourth and the fifth metal layer can be made thin by adopting a fourth semiconductor layer. Hereby, when patterning a third semiconductor layer and a fourth semiconductor layer, the first—the fifth metal layer can also be patterned collectively, and simplification of a manufacturing process can be aimed at also in this point.

A method of manufacturing a semiconductor device which has a MOS structure according to claim 22 concerning the present invention comprises the steps of (a) forming a gate insulating film over a first semiconductor layer and a second semiconductor layer, (b) forming a metal layer of a 1st layer over the gate insulating film, (c) leaving the metal layer of the 1st layer above the first semiconductor layer, and removing the metal layer of the 1st layer from an upper part of the second semiconductor layer, (d) forming a metal layer of a 2nd layer over the metal layer of the 1st layer, and the second semiconductor layer, (e) forming a metal layer of a 3rd layer over the metal layer of the 2nd layer, (f) forming a semiconductor layer for gate electrodes over the metal layer of the 3rd layer, and (g) patterning the metal layer of the 1st layer, the metal layer of the 2nd layer, the metal layer of the 3rd layer, and the semiconductor layer for gate electrodes, forming a first gate electrode in the first semiconductor layer upper part, and forming a second gate electrode above the second semiconductor layer.

Therefore, the semiconductor device according to claim 15 which has an MOS structure can be manufactured. In the especially first MOS structure, threshold voltage can be selected by the first, the second, the third metal layer, and the third semiconductor layer, and the threshold voltage in the second MOS structure can be selected by the fourth, the fifth metal layer, and the fourth semiconductor layer. In the first MOS structure, Fermi level pinning, depletion-ization of a gate electrode, etc. are solvable. Depletion-ization of a second gate electrode can be suppressed in the second MOS structure. Also in any of the first and the second gate electrode, the conductivity type of a polycrystalline silicon layer can be done in common, and a manufacturing process can be simplified. By adopting a third semiconductor layer in a first gate electrode, thickness of the first, the second, and a third metal layer can be made thin, and thickness of the fourth and a fifth metal layer can be made thin by adopting a fourth semiconductor layer in a second gate electrode. Hereby, when patterning the third and a fourth semiconductor layer, each metal layer can also be patterned collectively and manufacture becomes easy.

A semiconductor device which has a MOS structure according to claim 29 concerning the present invention comprises a first semiconductor layer which contained halogen in a front surface, a second semiconductor layer which contained nitrogen in a front surface, a first gate insulating film arranged over the first semiconductor layer, a first gate electrode which has a first metal layer arranged over the first gate insulating film, and a third semiconductor layer arranged over the first metal layer, a second gate insulating film arranged over the second semiconductor layer, and a second gate electrode which has a second metal layer arranged over the second gate insulating film, and a fourth semiconductor layer arranged over the second metal layer, wherein the first metal layer and the second metal layer are layers of the same material and thickness.

Therefore, since it has the first semiconductor layer into which the halogen was implanted, and the second semiconductor layer into which nitrogen was implanted, the threshold voltage of each gate electrode can be adjusted by adjusting the concentration of the element concerned implanted etc. Formation of the depletion layer in each gate electrode is solvable with formation of each metal layer.

A method of manufacturing a semiconductor device which has a MOS structure according to claim 31 concerning the present invention comprises the steps of (a) implanting halogen into a front surface of a first semiconductor layer, (b) implanting nitrogen into a front surface of a second semiconductor layer, (c) forming a gate insulating film over the first semiconductor layer and the second semiconductor layer, (d) forming a metal layer over the gate insulating film, (e) forming a semiconductor layer for gate electrodes over the metal layer, and (f) patterning the metal layer and the semiconductor layer for gate electrodes, forming a first gate electrode above the first semiconductor layer, and forming a second gate electrode above the second semiconductor layer.

Therefore, the semiconductor device according to claim 29 which has an MOS structure can be manufactured. Since it has especially a step which implants a halogen into a first semiconductor layer, and a step which implants nitrogen into a second semiconductor layer, the threshold voltage of each gate electrode can be adjusted by adjusting the concentration of the element concerned implanted etc. Since it has a step which forms a metal layer, formation of the depletion layer in each gate electrode is solvable.

### BRIEF DESCRIPTION OF THE DRAWINGS

FIG. 1 is a cross-sectional view showing the structure of the CMOS transistor concerning Embodiment 1 of the present invention;

FIGS. 2 to 12 are step cross-sectional views for explaining the manufacturing method of the CMOS transistor concerning Embodiment 1 of the present invention;

FIG. 13 is a drawing showing the SIMS analysis result for explaining the effect of the present invention;

FIG. 14 is a drawing showing the C-V measurement result for explaining the effect of the present invention;

FIG. 15 is a drawing showing the XRD analysis result for explaining the effect of the present invention;

FIG. 16 is a cross-sectional view showing the structure of the CMOS transistor concerning Embodiment 2 of the present invention;

FIGS. 17 to 21 are step cross-sectional views for explaining the manufacturing method of the CMOS transistor concerning Embodiment 2 of the present invention;

FIG. 22 is a cross-sectional view showing the structure of the CMOS transistor concerning Embodiment 3 of the present invention; and

FIGS. 23 to 28 are step cross-sectional views for explaining the manufacturing method of the CMOS transistor concerning Embodiment 3 of the present invention.

### DETAILED DESCRIPTION OF THE PREFERRED EMBODIMENTS

Hereafter, this invention is concretely explained based on the drawings in which the embodiments are shown.

### Embodiment 1

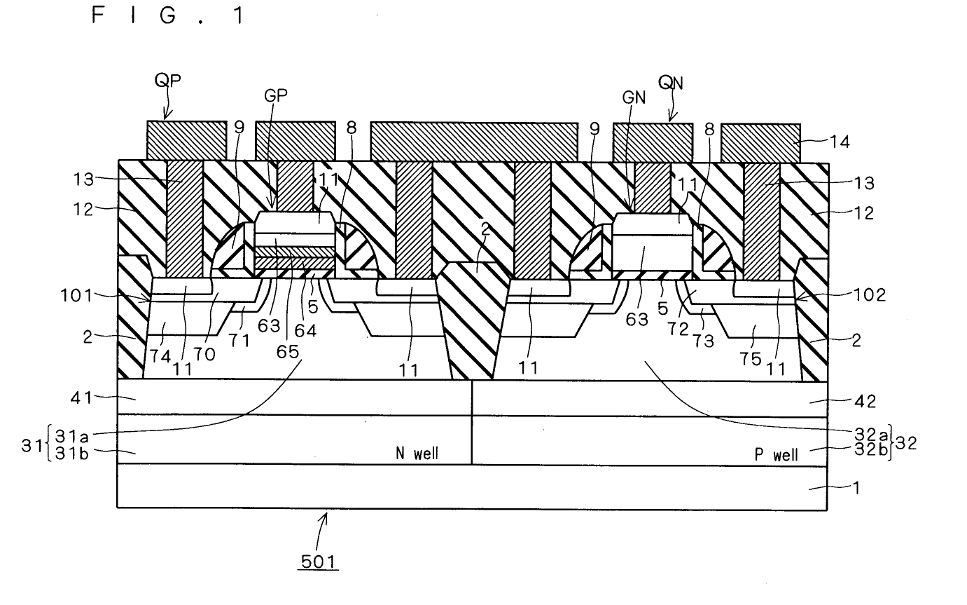

FIG. 1 is a cross-sectional view showing the structure of CMOS transistor 501 concerning this embodiment. CMOS transistor 501 is provided with PMOS transistor QP and NMOS transistor QN.

PMOS transistor QP is formed in N type well 31 (here, it can be grasped that N type well 31a is a first semiconductor layer). On the other hand, NMOS transistor QN is formed in P type well 32 (here, it can be grasped that P type well 32a is a second semiconductor layer). Both N type well 31 and P type well 32 are formed in one main surface (in FIG. 1, it is an upside) of semiconductor substrate 1. N type well 31a and P type well 32a are separated by element isolation insulator 2 (N type well 31b and P type well 32b are not separated by element isolation insulator 2 as FIG. 1 may show in addition). Semiconductor substrate 1, N type well 31, and P type well 32 all adopt silicon as the main ingredients, for example. Unless it refuses in particular, silicon is employable similarly about other impurity layers. A silicon oxide is employable as element isolation insulator 2, for example.

On N type well 31b formed on semiconductor substrate 1, N type element isolation diffusion layer 41 is formed. On the other hand, P type element isolation diffusion layer 42 is formed on P type well 32b formed on semiconductor substrate 1.

PMOS transistor QP has gate electrode (it can be grasped as a first gate electrode) GP, and P type source/drain layer 101 of a pair. N type well 31a which is inserted between P type source/drain layer 101 of a pair, and stands face to face against gate electrode GP functions as a channel region of PMOS transistor QP.

On the other hand, NMOS transistor QN has gate electrode (it can be grasped as a second gate electrode) GN, and N type source/drain layer 102 of a pair. P type well 32a which is inserted between N type source/drain layer 102 of a pair, and stands face to face against gate electrode GN functions as a channel region of NMOS transistor QN.

P type source/drain layer 101 includes main layer 74 of a P type, and sublayers 70 and 71 whose bottoms are shallower seen from a transistor formation surface than the bottom of main layer 74. Sublayer 70 is a source/drain extension of a P type, and projects in the channel region side rather than main layer 74. Sublayer 71 is a pocket of an N type, and its bottom is deeper seen from the above-mentioned transistor formation surface than the bottom of source/drain extension 70, and it projects in the channel region side rather than source/drain extension 70.

N type source/drain layer 102 includes main layer 75 of an N type, and sublayers 72 and 73 seen from the above-mentioned transistor formation surface whose bottoms are shallower than the bottom of main layer 75. Sublayer 72 is a source/drain extension of an N type, and projects in the channel region side rather than main layer 75. Sublayer 73 is a pocket of a P type, and its bottom is deeper seen from the above-mentioned transistor formation surface than the bottom of source/drain extension 72, and it projects in the channel region side rather than source/drain extension 72.

Sidewall 8 of L character type in section and spacer 9 with which the internal corner of sidewall 8 is filled are formed in any circumference of gate electrode GP and GN. As a material of sidewall 8 and spacer 9, an oxide film and a nitride film are adopted, respectively, for example.

Interlayer insulation film 12 is formed on element isolation insulator 2, source/drain extensions 70 and 72, sidewall 8, spacer 9, and gate electrodes GP and GN. As a material of interlayer insulation film 12, an oxide film is adopted, for example.

Contact plug 13 penetrates interlayer insulation film 12, and is formed. Source/drain extensions 70 and 72 are formed in the position of the lower end of contact plug 13. In the position of the lower end of other contact plugs 13, silicide layer 11 which forms a part of gate electrodes GP and GN is formed. That is, source/drain extensions 70 and 72, and gate electrode GP and GN are electrically connected with contact plug 13 via the silicide layer 11 concerned. Silicide layer 11 is made of nickel silicide, for example. Although it is desirable to be formed from a viewpoint which makes electric connection good as for silicide layer 11, it is not indispensable.

In the position of the upper end of contact plug 13, wiring layer 14 is formed on interlayer insulation film 12, and contact plug 13 and wiring layer 14 are electrically connected. Metal can be used for each of materials of contact plug 13, and materials of wiring layer 14.

Although the case where source/drain layers 101,102 which adjoin mutually are directly connected by wiring layer 14 is exemplified in FIG. 1, the present invention is not limited to this structure. However, the present invention is preferred, when gate electrodes GP and GN are connected further mutually and a CMOS inverter is formed. It is because it exists as a background of the present invention to adjust threshold voltage about a plurality of MOS structures and the adjustment concerned has big influence on operation of a CMOS inverter.

PMOS transistor QP has gate insulating film (it can be grasped as a first gate insulating film) 5 between gate electrode GP, and the channel region of N type well 31a. NMOS transistor QN has gate insulating film (it can be grasped as a second gate insulating film) 5 between gate electrode GN, and the channel region of P type well 32a. As gate insulating film 5, except for silicon oxide or silicon oxynitriding, hafnium oxides whose dielectric constant is high, such as a hafnium oxide film (HfO₂), a hafnium oxynitride film (HfON), a hafnium silicate film (HfxSiyOz), a hafnium silicon oxynitride film (HfSiON), a hafnium aluminate film (HfxAlyOz), a hafnium aluminum oxynitride film (HfAlON), are employable.

Gate electrode GP includes first metal layer 64, second metal layer 65, polycrystalline silicon layer (it can be grasped as a third semiconductor layer) 63, and silicide layer 11 sequentially from the gate insulating film 5 side.

Here, first metal layer 64 stands face to face against the channel region formed in N type well 31a via gate insulating film 5. That is, the first metal layer 64 concerned mainly determines the work function of gate electrode GP of PMOS transistor QP. Therefore, the material which has a work function suitable for operation of the PMOS transistor QP concerned turns into material of first metal layer 64 (that is, as for first metal layer 64, the material is chosen from a viewpoint of the work function of PMOS transistor QP).

Second metal layer 65 can suppress more that substances, such as an impurity, silicon, etc. from polycrystalline silicon layer 63, are diffused in the direction in which gate insulating film 5 is formed. That is, the above-mentioned diffusion suppression effect of second metal layer 65 is higher than first metal layer 64 (therefore, as for second metal layer 65, the material is chosen from a viewpoint of the above-mentioned diffusion suppression effect).

The function differs between first metal layer 64 and second metal layer 65 as the above may show. That is, first metal layer 64 has the work which mainly determines the work function of gate electrode GP which forms PMOS transistor QP. On the other hand, second metal layer 65 mainly has the work which suppresses diffusion of substances, such as an impurity, silicon, etc. from polycrystalline silicon layer 63. And when forming the first and the second metal layers 64 and 65, the material and the manufacture conditions which specialized in the function concerned are chosen.

The threshold voltage of gate electrode GP is determined by first metal layer 64, second metal layer 65, and polycrystalline silicon layer 63 in PMOS transistor QP.

Gate electrode GN includes polycrystalline silicon layer (it can be grasped as a fourth semiconductor layer) 63, and silicide layer 11 sequentially from the gate insulating film 5 side.

When adopting polycrystalline silicon as a gate electrode in a CMOS transistor, the conductivity type of these gate electrodes is usually changed. It is because it is necessary to adjust mutual threshold voltage by the PMOS transistor and an NMOS transistor.

However, in this embodiment, it cannot be said that polycrystalline silicon layer 63 of gate electrode GP and the channel region of PMOS transistor QP confront each other only via gate insulating film 5. Therefore, the conductivity type of polycrystalline silicon layer 63 of gate electrode GP does not determine the threshold voltage of PMOS transistor QP promptly. On the other hand, since NMOS transistor QN has gate electrode GN, it is desirable to adopt an N type as the conductivity type of polycrystalline silicon layer 63 of gate electrode GN. Therefore, in the present invention, the conductivity type of polycrystalline silicon layer 63 can be done in common also in any of gate electrode GP and GN. In this embodiment, the N type which fitted gate electrode GN as the conductivity type concerned is adopted.

Of course, first metal layer 64 of gate electrode GP and a channel region confront each other only via gate insulating film 5. Therefore, it is desirable to adopt the metal which has a work function (that is, comparatively high work function) suitable for PMOS transistor QP as a metallic material of first metal layer 64. When adopting silicon as the main ingredients of N type well 31, it is desirable to have a work function (about 5.1 eV) near the valence band of silicon as a metallic material of the first metal layer 64 concerned. It cannot be said that second metal layer 65 and a channel region confront each other only via gate insulating film 5. Therefore, the work function of the second metal layer 65 concerned does not need to be as high as the work function of first metal layer 64 (when putting in another way, the work function of the first metal layer is larger than the work function of the second metal layer).

Here, as a metallic material which satisfies the requirements for metal layers 64 and 65, for example, titanium nitride (TiN), tungsten nitride (WN), nickel (Ni), rhenium (Re), iridium (Ir), platinum (Pt), ruthenium oxide (RuO₂), iridium oxide (IrO₂), and molybdenum nitride (MoN) can be mentioned.

Investigation which uses titanium nitride (TiN) as a metal gate electrode material is also advanced. However, since the work function is set to about 4.6 eV, as for the TiN film formed by the conventional sputtering technique, in an NMOS transistor and a PMOS transistor, threshold voltage Vₜₕ becomes high. However, with the thermalCVD method using TiCl₄ and NH₃, at the low temperature less than 450° C., by forming a TiN film as first metal layer 64, the damage to gate insulating film 5 can be suppressed, and gate leakage current can be reduced, and a work function of 4.8 eV or more suitable for PMOS transistor QP can be acquired.

Thus, in this embodiment, the portion in contact with gate insulating film 5 is made into first metal layer 64 in gate electrode GP of PMOS transistor QP which has the first threshold voltage. Therefore, each problem, such as the above-mentioned Fermi level pinning, formation of gate electrode depletion, etc. which may be generated in PMOS transistor QP, is solvable.

In this embodiment, gate electrode GP which forms PMOS transistor QP is formed by first metal layer 64, second metal layer 65, and polycrystalline silicon layer 63. Therefore, each metal layers 64 and 65 and polycrystalline silicon layer 63 can adjust (control) the threshold voltage of PMOS transistor QP to a suitable value. That is, by the part in which each metal layers 64 and 65 are formed, the threshold voltage of PMOS transistor QP can be adjusted (controlled) with more sufficient accuracy (finely).

In addition to the structure of the above-mentioned gate electrode GP, in this embodiment, the portion in contact with gate insulating film 5 is made into polycrystalline silicon layer 63 (semiconductor layer) in gate electrode GN of NMOS transistor QN which has the second threshold value. Therefore, polycrystalline silicon layer 63 of the same conductivity type as polycrystalline silicon layer 63 formed in NMOS transistor QN concerned can be formed on the above-mentioned second metal layer 65 according to the structure concerned. That is, since it becomes unnecessary to introduce the impurity of a different conductivity type into each polycrystalline silicon layer 63, simplification of a manufacturing process can be aimed at.

By the way, the laminated structure by which a gate insulating film, the metal layer of one layer, and polycrystalline silicon were laminated by the order concerned is also employable as a structure of gate electrode GP (that is, the laminated structure whose metal layer is only one layer is also employable).

However, as mentioned above, the work function of an MOS transistor is mainly determined by the metal layer directly formed on a gate insulating film. Therefore, it is necessary to determine a proper work function from a viewpoint of operation of PMOS transistor QP, and material, a manufacturing process, etc. of the metal layer directly formed on a gate insulating film are determined in this viewpoint.

On the other hand, substances diffused in the direction of a gate insulating film from a polycrystalline silicon layer, such as silicon, impurity diffusion, etc. from the polycrystalline silicon layer concerned, must also be suppressed. This is because originating in diffusion of the impurity concerned, silicon, etc., an electrical property is changed. Here, diffusion of substances, such as the above-mentioned impurity and silicon, is generated at the times of formation of a polycrystalline silicon layer, or high temperature heat treatment, such as subsequent activation annealing.

However, it is very difficult from a viewpoint of a manufacturing process to form the metal layer of one layer which has a proper work function from a viewpoint of operation of PMOS transistor QP, and has a diffusion suppression effect of substances, such as the above-mentioned silicon. It is because the process which produces the metal layer which has such a work function, and the process which produces the metal layer which has the above-mentioned high diffusion suppression effect generally differ. The structure of the metal layer which has such a work function may differ from the structure of the metal layer which has the above-mentioned high diffusion suppression effect.

Then, in this embodiment, first metal layer 64 is formed on gate insulating film 5, and second metal layer 65 is formed on the first metal layer 64 concerned. Therefore, the structure and the manufacturing process of the first metal layer 64 concerned can be chosen and determined so that first metal layer 64 may have a proper work function from a viewpoint of operation of PMOS transistor QP. On the other hand, the structure and the manufacturing process of the second metal layer 65 concerned can be chosen and determined so that second metal layer 65 may have the above-mentioned higher diffusion suppression effect.

Thus, in this embodiment, since production of each metal layers 64 and 65 concerned becomes easy by forming separately independently metal layers 64 and 65 which specialized in each above-mentioned function, the difficulty of a manufacturing process is avoidable. In PMOS transistor QP which is a transistor of the side which becomes remarkable the diffusion to the channel region of the impurity introduced into the polycrystalline silicon adopted in a gate electrode or silicon in a CMOS transistor, change of the electrical property resulting from diffusion of the impurity concerned, silicon, etc. is avoidable.

Suppose that the metal layer concerned was formed from a viewpoint of the above-mentioned proper work function by making only into one layer the metal layer which forms gate electrode GP. In the structure concerned, the metal layer concerned of one layer cannot fully suppress them, although it has the above-mentioned diffusion suppression effects, such as silicon and an impurity, to some extent (diffusion in particular of silicon cannot be suppressed). Therefore, in order to fully demonstrate a silicon and impurity diffusion suppression effect, it is more useful to form gate electrode GP from metal layers 64 and 65 of the above-mentioned two layer (in order to demonstrate the diffusion suppression effect of silicon especially).

When a hafnium oxide is adopted as gate insulating film 5 and polycrystalline silicon layer 63 of gate electrode GP contacts gate insulating film 5, it is easy to generate the problem of an interface state of the so-called Fermi level pinning. However, in this embodiment, first metal layer 64 contacts gate insulating film 5, second metal layer 65 which prevents diffusion exists on it further, and this problem can also be avoided. Therefore, the present invention is preferred, when adopting a hafnium oxide as gate insulating film 5 and raising the dielectric constant.

In this embodiment, first metal layer 64 and second metal layer 65 can be formed with both titanium nitrides. It becomes possible to form first metal layer 64 which has a work function (4.8 eV or more) suitable for PMOS transistor QP, without giving a damage to gate insulating film 5, when titanium nitride is adopted as each metal layers 64 and 65. It becomes possible to form second metal layer 65 which can suppress more diffusion of silicon, an impurity, etc. from polycrystalline silicon layer 63. Facilitation of the etching step at the time of patterning each metal layers 64 and 65 simultaneously with polycrystalline silicon layer 63 is done by using first metal layer 64 and second metal layer 65 as the same titanium nitride.

In this embodiment, polycrystalline silicon layer 63 is adopted in gate electrode GP as above-mentioned. Hereby, thickness of first metal layer 64 and second metal layer 65 can be made thin. Therefore, when patterning each polycrystalline silicon layer 63 in gate electrode GP and GN, first metal layer 64 and second metal layer 65 concerned can also be patterned collectively, and manufacture becomes easy also from this viewpoint.

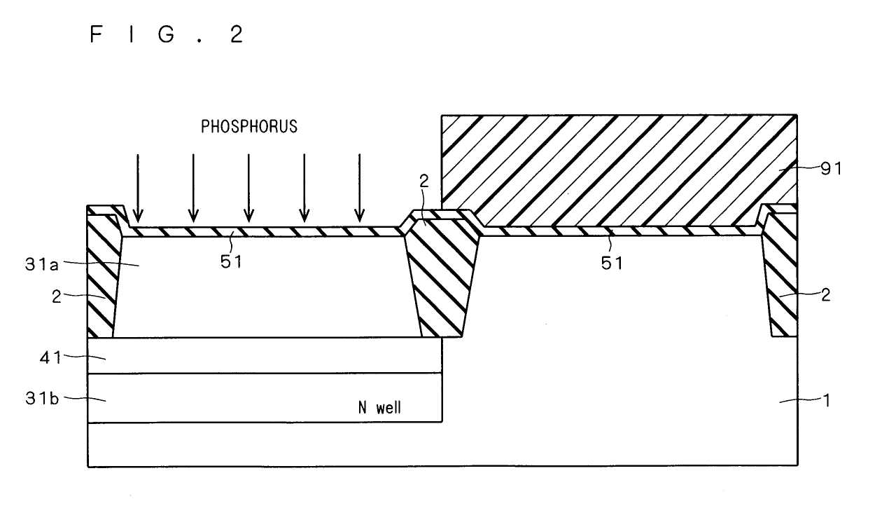

Next, the manufacturing method of the semiconductor device (CMOS transistor 501) concerning this embodiment which has a MOS structure is explained. FIG. 2 through FIG. 12 are the cross-sectional views showing the manufacturing process of CMOS transistor 501 in order.

First, with reference to FIG. 2, element isolation insulator 2 is isolated to one main surface of semiconductor substrate 1, and two or more are formed in it. The STI (Shallow Trench Isolation) method is adopted as formation of element isolation insulator 2, for example. Oxide film 51 for implantation is formed in the main surface of semiconductor substrate 1.

In the region which forms NMOS transistor QN later, photoresist 91 is formed on the above-mentioned main surface. In FIG. 2 through FIG. 12, the case where form PMOS transistor QP in the left-hand side of element isolation insulator 2 shown in the center, and NMOS transistor QN is formed in right-hand side is exemplified.

Photoresist 91 is used as a mask and an N type impurity is introduced into a main surface via oxide film 51 for implantation. As an N type impurity implanted, phosphorus is employable. By implantation of an N type impurity, N type wells 31a and 31b and N type element isolation diffusion layer 41 are formed. Photoresist 91 is removed after that.

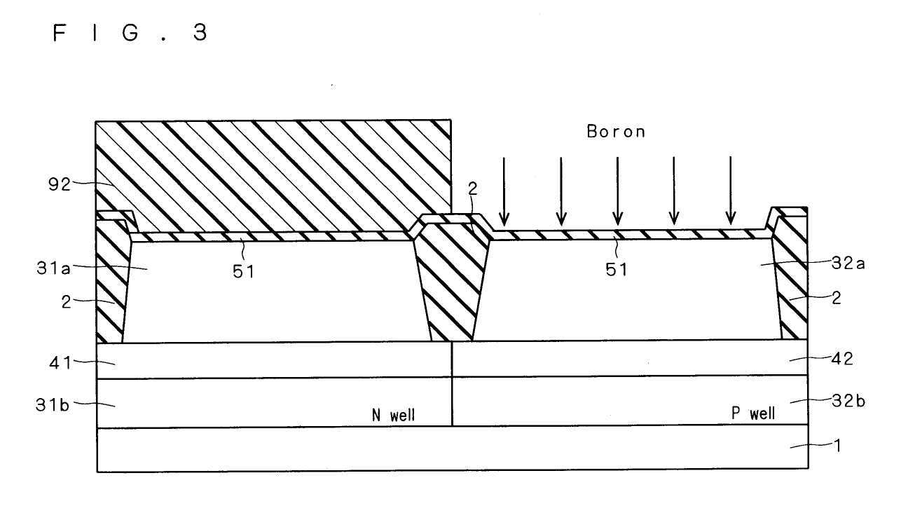

In the region which forms PMOS transistor QP later with reference to FIG. 3, photoresist 92 is formed on a main surface. Photoresist 92 is used as a mask and a P type impurity is introduced into a main surface via oxide film 51 for implantation. As a P type impurity implanted, boron is employable. By implantation of a P type impurity, P type wells 32a and 32b and P type element isolation diffusion layer 42 are formed. Photoresist 92 is removed after that.

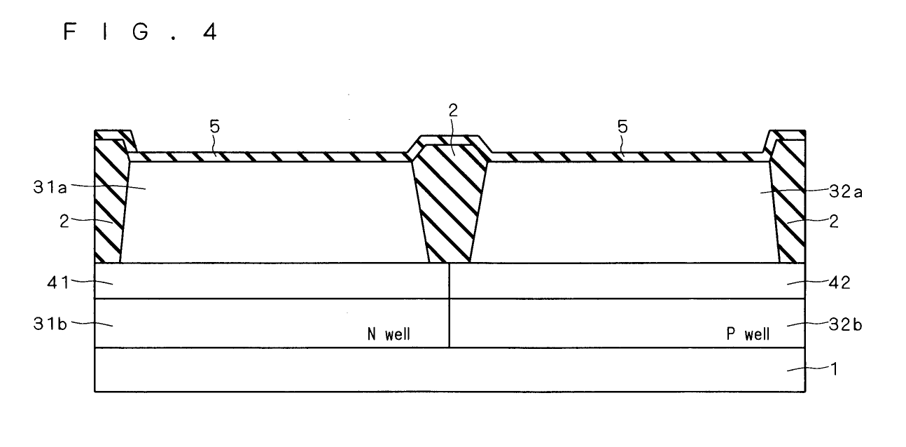

Oxide film 51 for implantation is removed with reference to FIG. 4, and gate insulating film 5 is formed on a main surface in both N type well 31a and P type well 32a. Like previous statement as gate insulating film 5, hafnium silicon oxynitride (HfSiON) is employable.

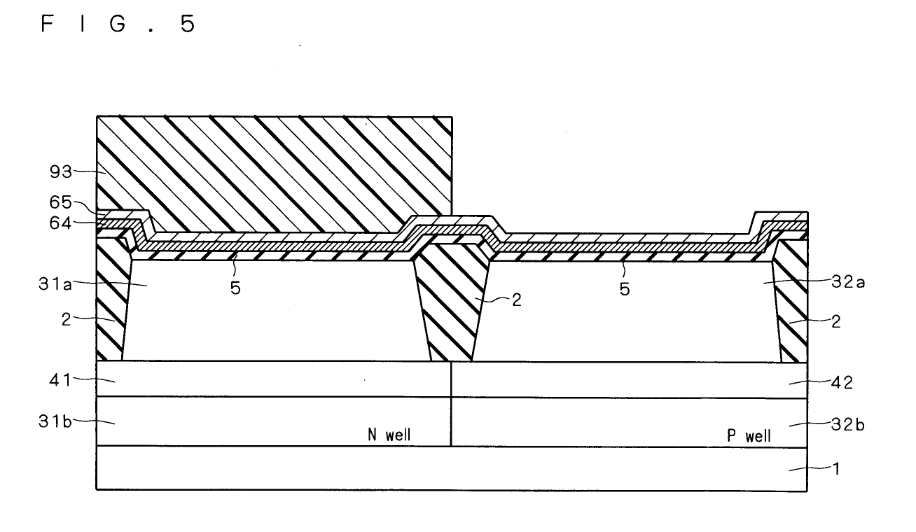

With reference to FIG. 5, the whole surface exposed by the main surface side is covered, and first metal layer 64 is formed by the thickness mentioned later on gate insulating film 5. Furthermore, second metal layer 65 is formed by thickness of 10 nm on first metal layer 64.

The titanium nitride (TiN) generated, for example by the CVD (Chemical Vapor Deposition) method is adopted as first metal layer 64. The ALD method (ALD: Atomic Layer Deposition) or the physical vapor deposition (sputtering) (PVD: Physical Vapor Deposition) of a low damage may be used except for a CVD method. It must be the method of not giving a damage to gate insulating film 5 and not degrading the characteristics of gate insulating film 5.

In the case of formation of second metal layer 65, since there is first metal layer 64, it is satisfactory also by the technique of giving a damage somewhat, and a sputtering technique with few impurities is good. In order to suppress diffusion of substances, such as silicon, an impurity, etc. from polycrystalline silicon 63 later formed on second metal layer 65, to form second metal layer 65 at a temperature higher than the forming temperature of first metal layer 64 is desired. As the second metal layer 65 concerned, as mentioned above, titanium nitride etc. is employable.

Now, with reference to FIG. 5, photoresist 93 is formed on second metal layer 65 above N type well 31a.

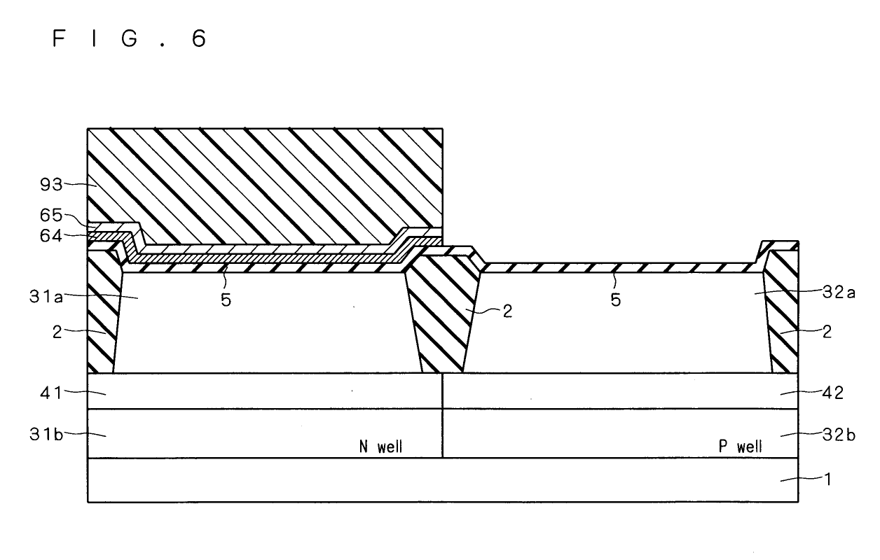

With reference to FIG. 6, second metal layer 65 and first metal layer 64 are patterned by using photoresist 93 as a mask. Hereby, first metal layer 64 and second metal layer 65 are removed in the upper part of P type well 32a, and are left behind in the upper part of N type well 31a. Photoresist 93 is removed after that.

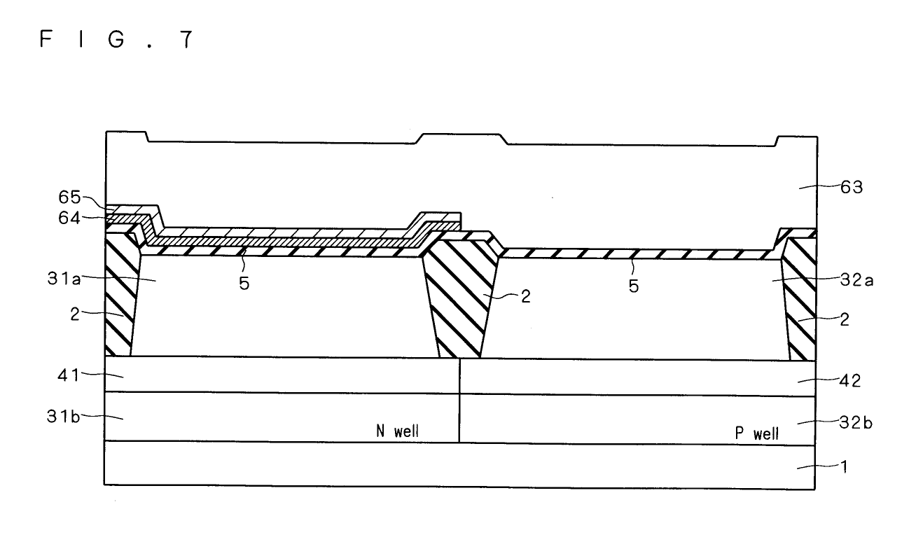

With reference to FIG. 7, the whole surface exposed by the main surface side is covered, and polycrystalline silicon layer 63 is formed. In the upper part of N type well 31a, polycrystalline silicon layer 63 will be formed on second metal layer 65, and it will be formed on gate insulating film 5 in the upper part of P type well 32a. In order to use the conductivity type of polycrystalline silicon layer 63 as an N type, it is desirable to form polycrystalline silicon layer 63, introducing the impurity (for example, phosphorus) of an N type.

After forming polycrystalline silicon layer 63, also by implanting the impurity of an N type from the front surface, the conductivity type of polycrystalline silicon layer 63 can be used as an N type. However, the side which forms polycrystalline silicon layer 63 introducing the impurity of an N type can reduce the generation of the depletion layer at the side of gate insulating film 5 of gate electrode GN (refer to FIG. 1) rather than the case where ion implantation is performed to near the gate insulating film 5. The thickness and impurity concentration of polycrystalline silicon layer 63 are set, for example as 100 nm and 10²⁰ cm⁻³, respectively.

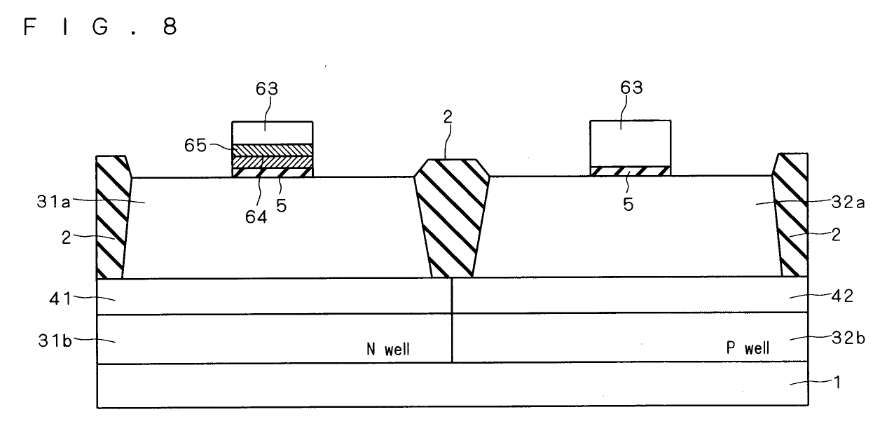

With reference to FIG. 8, well-known photolithography technology is adopted and polycrystalline silicon layer 63 and gate insulating film 5 are patterned. At the step which etches polycrystalline silicon layer 63, first metal layer 64 and second metal layer 65 can also be etched collectively. First metal layer 64 offers suitable band structure between N type wells 31a via gate insulating film 5. The degree that silicon or the impurity in polycrystalline silicon layer 63 do not diffuse to gate insulating film 5 more than second metal layer 65 at the time of heat treatment of polycrystalline silicon layer 63 film formation, subsequent activation annealing, etc. is sufficient for first metal layer 64. It is not necessary to thicken thickness of first metal layer 64 and second metal layer 65 concerned from the viewpoint concerned. It is suitable that the total of the thickness of first metal layer 64 and the thickness of second metal layer 65 is about 1/10 of the thickness of polycrystalline silicon layer 63.

When etching the polycrystalline silicon layer adopted as a gate electrode, usually the amount of over-etchings is set about 1/10 of the thickness of a polycrystalline silicon layer. At this embodiment, polycrystalline silicon layer 63 is formed at the same step as both the upper part of P type well 32a, and the upper part of N type well 31a. Therefore, an etching step can be simplified by setting the total of the thickness of first metal layer 64, and the thickness of second metal layer 65 below the amount of over-etchings at the time of patterning polycrystalline silicon layer 63 in the upper part of N type well 31a (that is, to 1/10 or less of the thickness of a polycrystalline silicon layer).

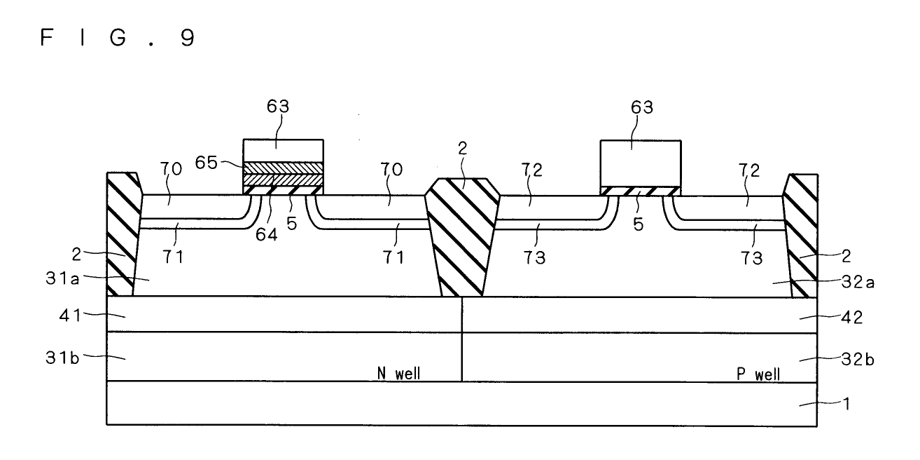

With reference to FIG. 9, above N type well 31a, source/drain extension 70 is formed by using the laminated structure of patterned polycrystalline silicon layer 63/second metal layer 65/first metal layer 64/gate insulating film 5 as a mask. Above P type well 32a, source/drain extension 72 is formed by using the laminated structure of patterned polycrystalline silicon layer 63/gate insulating film 5 as a mask.

Although not illustrated in detail, when forming source/drain extension 70, the upper part of P type well 32a is covered by photoresist, and a P type impurity (for example, boron) is introduced to N type well 31a with ion implantation. And further, in order to inhibit a short channel effect, ion implantation is aslant performed for an N type impurity (for example, arsenic) to a main surface, and pocket 71 is formed. Similarly, when forming source/drain extension 72, the upper part of N type well 31a is covered by photoresist, and an N type impurity (for example, arsenic) is introduced to P type well 32a with ion implantation. And further, in order to inhibit a short channel effect, ion implantation is aslant performed for a P type impurity (for example, boron) to a main surface, and pocket 73 is formed.

The dose amount and implantation energy of these ion implantation are decided by the depth and the resistance which are required of source/drain extensions 70 and 72 or pockets 71 and 73.

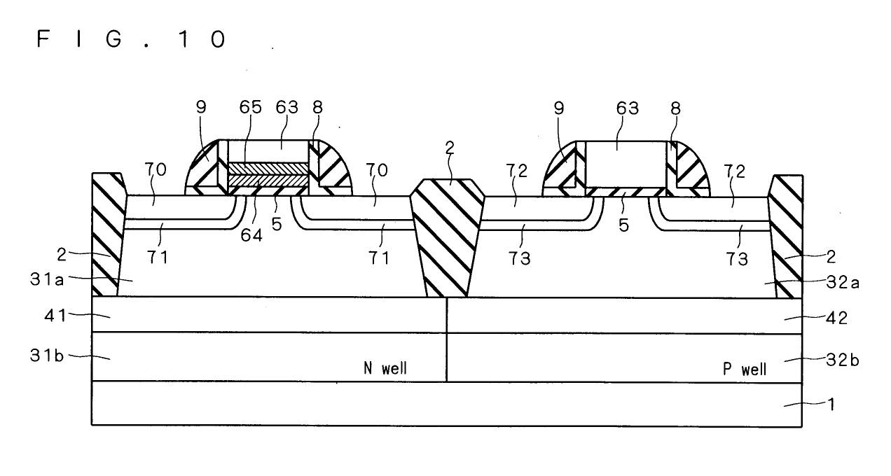

An oxide film and a nitride film are formed in this order covering all over the surface which exposes in the main surface side, and the oxide film and the nitride film concerned are etched back. Hereby, as shown in FIG. 10, sidewall 8 and spacer 9 are formed.

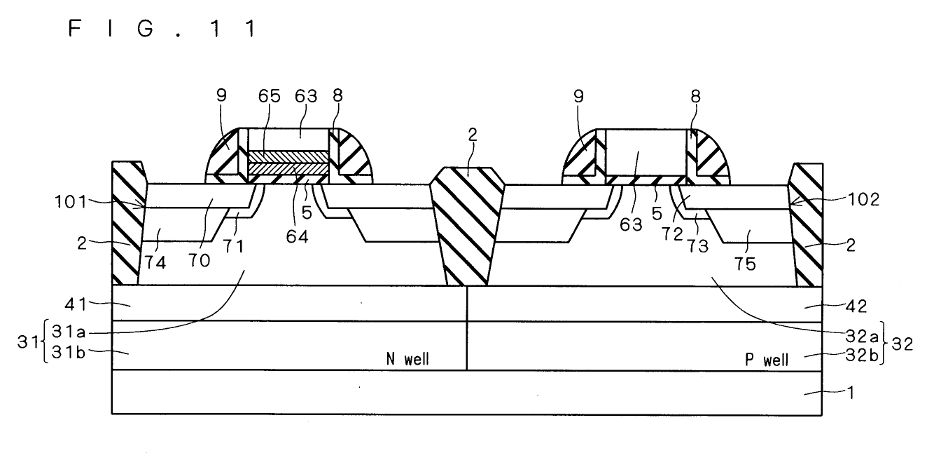

With reference to FIG. 11, above N type well 31a, the laminated structure of polycrystalline silicon layer 63/second metal layer 65/first metal layer 64/gate insulating film 5, and sidewall 8 and spacer 9 of the circumference are used as a mask. Main layer 74 is formed by performing predetermined ion implantation processing. Above P type well 32a, main layer 75 is formed by performing predetermined ion implantation processing by using the laminated structure of polycrystalline silicon layer 63/gate insulating film 5, and sidewall 8 and spacer 9 of the circumference as a mask.

Although not illustrated in detail, when forming main layer 74, the upper part of P type well 32a is covered by photoresist, and a P type impurity (for example, boron) is introduced with ion implantation to N type well 31a also including sublayers 70 and 71. When forming main layer 75 similarly, the upper part of N type well 31a is covered by photoresist, and an N type impurity (for example, arsenic) is introduced with ion implantation to P type well 32a also including sublayers 72 and 73. And annealing for activating source/drain layer 101,102 is performed. Lamp annealing is adopted as annealing, for example.

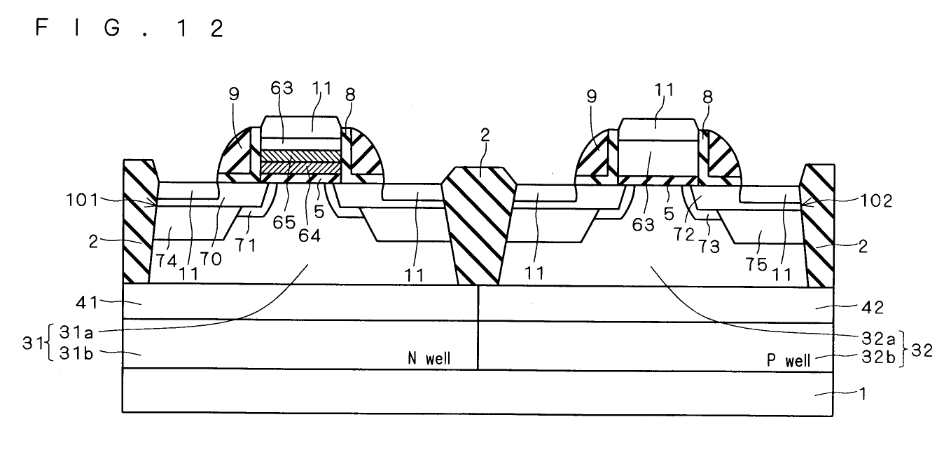

The metal for silicide, for example, nickel, is formed covering all over the surface exposed by the main surface side, and annealing performs the first silicidation. And an unreacted metal for the above-mentioned silicide is removed, annealing is performed further, the second silicidation is performed, the phase transition of silicide is urged, and resistance of silicide is lowered. Hereby, as shown in FIG. 12, silicide layer 11 is formed in the exposed surface of source/drain extensions 70 and 72 and polycrystalline silicon layer 63.

Then, interlayer insulation film 12, contact plug 13, and wiring layer 14 are formed by a well-known manufacturing process, and CMOS transistor 501 shown in FIG. 1 is obtained.

As mentioned above, in order to etch first metal layer 64 and second metal layer 65 along with etching of polycrystalline silicon layer 63, the thinner side of the total of the thickness of first metal layer 64 and the thickness of second metal layer 65 is desirable. However, first metal layer 64 needs to have a suitable work function, and it is thought from this request that thickness of 2 nm or more (especially about 2 nm-5 nm) is required. Second metal layer 65 needs to prevent diffusion of substances, such as silicon and an impurity, more surely, and it is thought from this request that thickness of 5 nm or more (especially about 5 nm-10 nm) is required.

What is necessary is just to implant halogen ion (for example, fluorine ion) moderately with an above-mentioned structure, into the front surface of N type well 31a on which gate electrode GP is formed, when the further adjustment of threshold voltage (Vₜₕ) is required. What is necessary is just to implant N₂ (nitrogen ion) moderately into the front surface of P type well 32a on which gate electrode GN is formed. For example, each ion implantation for the above-mentioned threshold voltage adjustment can be performed on the conditions whose concentration of fluorine ion is about 1˜3×10¹⁵/cm², and can be performed on the conditions whose ion acceleration voltage is about 7 keV. It can carry out on the conditions whose concentration of N₂ ion is about 0.5˜2×10¹⁵/cm², and can carry out on the conditions whose ion acceleration voltage is about 22 keV.

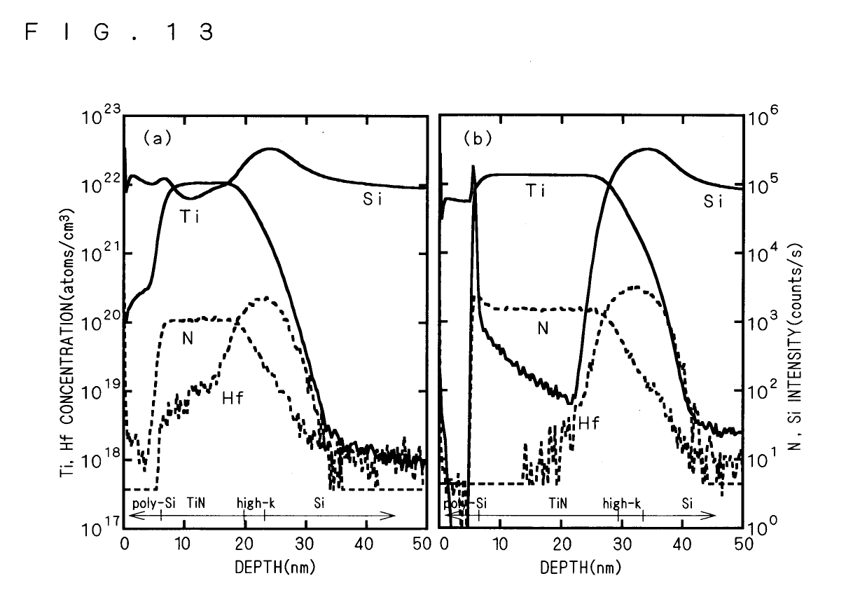

FIG. 13 is experimental data in which it is shown that diffusion of the silicon from polycrystalline silicon layer 63 is suppressed by forming a second metal layer. The experimental data (a) on the left of FIG. 13 is a depth direction SIMS analysis result after 1000° C. heat treatment of Poly-Si/CVD-TiN (first metal layer)/HfSiON (gate insulating film)/Si structure. On the other hand, the experimental data (b) on the right of FIG. 13 is a depth direction SIMS analysis result after 1000° C. heat treatment of Poly-Si/PVD-TiN (second metal layer)/CVD-TiN (first metal layer)/HfSiON (gate insulating film)/Si structure.

By forming the second metal layer (PVD-TiN) which specialized in the diffusion control effects of, such as the above-mentioned silicon between Poly-Si/CVD-TiN (first metal layer) with an above-mentioned manufacturing method as shown in FIG. 13, diffusion of the silicon from Poly-Si can be suppressed (as shown in FIG. 13(b), there are quite few amounts of distribution of the silicon in the depth in which the first metal layer and the second metal layer are formed as compared with the case of FIG. 13(a)).

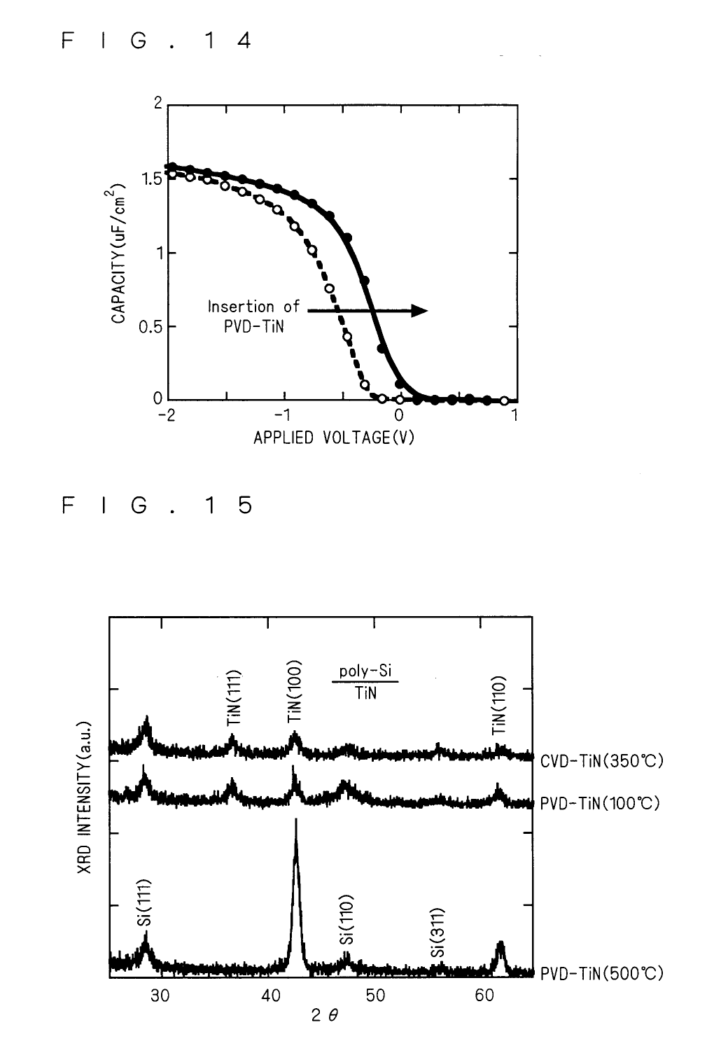

Another experimental data for explaining the effect of being performed by forming second metal layer 65 is shown in FIG. 14.

Using an LOCOS capacitor, Poly-Si/CVD-TiN (first metal layer)/HfSiON (gate insulating film)/Si structure, and Poly-Si/PVD-TiN (second metal layer)/CVD-TiN (first metal layer)/HfSiON (gate insulating film)/Si structure are produced. Both 1000° C. heat treatment was performed and the C-V (Capacitance-Voltage) curve was measured after that. The measurement result concerned is shown in FIG. 14.

By the way, in CVD-TiN/HfSiON/Si structure, the effective work function estimated from a C-V curve was set to 4.92 eV, and the comparatively high work function suitable for a PMOS transistor was acquired (Nonpatent Literature 2). On the other hand, with Poly-Si/CVD-TiN/HfSiON/Si structure (that is, structure which formed the polycrystalline silicon layer on the first metal layer), when estimated from the data of the white circle of FIG. 14, the effective work function was set to about 4.6 eV, and shifted to the mid gap.

Thus, inventors thought that diffusion of the silicon from Poly-Si was the cause that the work function shifted to the mid gap by laminating Poly-Si on a first metal layer. Then, in order to suppress this diffusion, Poly-Si/PVD-TiN (second metal layer)/CVD-TiN (first metal layer)/HfSiON (gate insulating film)/Si structure in which PVD-TiN (second metal layer) were inserted between Poly-Si/CVD-TiN (first metal layer) was created.

The data of the black dot of FIG. 14 is Poly-Si/PVD-TiN (second metal layer)/CVD-TiN (first metal layer)/HfSiON (gate insulating film)/Si structure concerned. When estimated from the data of the black dot concerned, it turned out that an effective work function is set to about 4.8 eV, and a work function suitable for a PMOS transistor is acquired.

The black dot data of FIG. 14 is a case where PVD-TiN (second metal layer) is formed on the film formation conditions in 500 ° C. in Poly-Si/PVD-TiN (second metal layer)/CVD-TiN (first metal layer)/HfSiON (gate insulating film)/Si structure concerned. On the other hand, when PVD-TiN was formed by 100° C. in Poly-Si/PVD-TiN (second metal layer)/CVD-TiN (first metal layer)/HfSiON (gate insulating film)/Si structure concerned, it was the same as Poly-Si/CVD-TiN/HfSiON/Si structure, and the work function shifted to the mid gap (data illustration is not done).

That is, when PVD-TiN is formed by low-temperature 100° C. from the manufacturing temperature of CVD-TiN, it is thought that diffusion of the silicon from Poly-Si cannot be suppressed. In other words, when PVD-TiN (second metal layer) is formed at a temperature (for example, more than 500° C.) higher than the manufacturing temperature of CVD-TiN (first metal layer), it originates in the PVD-TiN (second metal layer) concerned, and diffusion of the silicon from Poly-Si is suppressed.

Inventors examined the crystal structure of second metal layer 65 which has diffusion suppression effects of, such as the above-mentioned silicon.

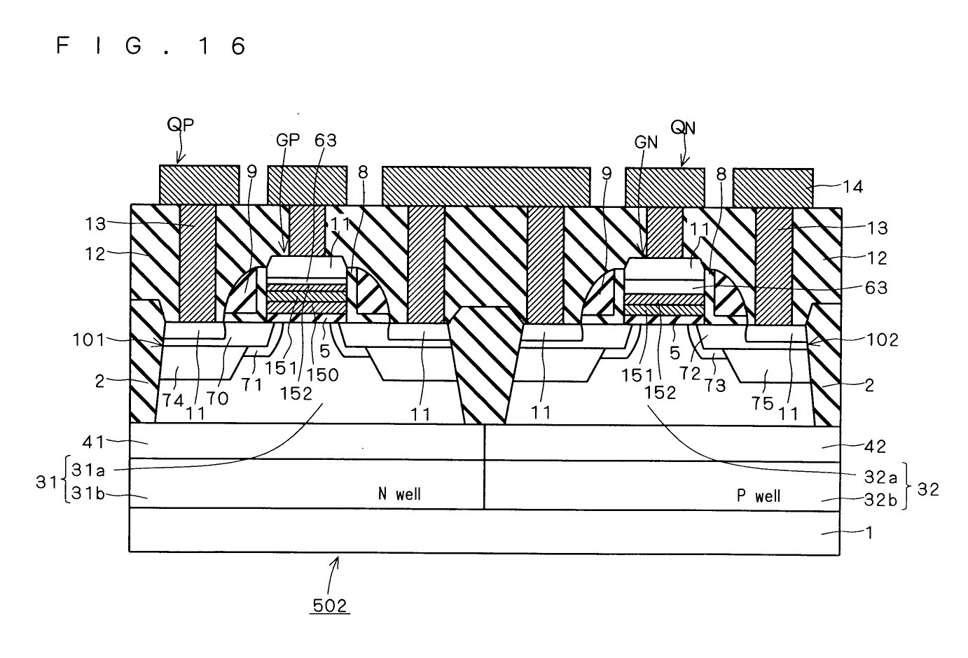

In FIG. 15, the XRD pattern after 1000° C. heat treatment of Poly-Si/CVD-TiN (metal layer, forming temperature 350° C.)/SiON (gate insulating film)/Si structure, Poly-Si/PVD-TiN (metal layer, forming temperature 100° C. )/SiON (gate insulating film)/Si structure, and Poly-Si/PVD-TiN (metal layer, forming temperature 500° C. )/SiON (gate insulating film)/Si structure, is shown.

Only the structure of having the PVD-TiN metal layer produced by forming temperature 500° C. has the above-mentioned silicon diffusion suppression effect (that is, the PVD-TiN metal layer produced by the 500° C. concerned can be grasped as a second metal layer). Only the PVD-TiN metal layer formed by the 500° C. concerned was doing orientation to the surface (200) as a result of FIG. 15. It turns out that the TiN film which did orientation to the surface (200) has a diffusion suppression effect of the above-mentioned silicon when putting in another way.

### Embodiment 2

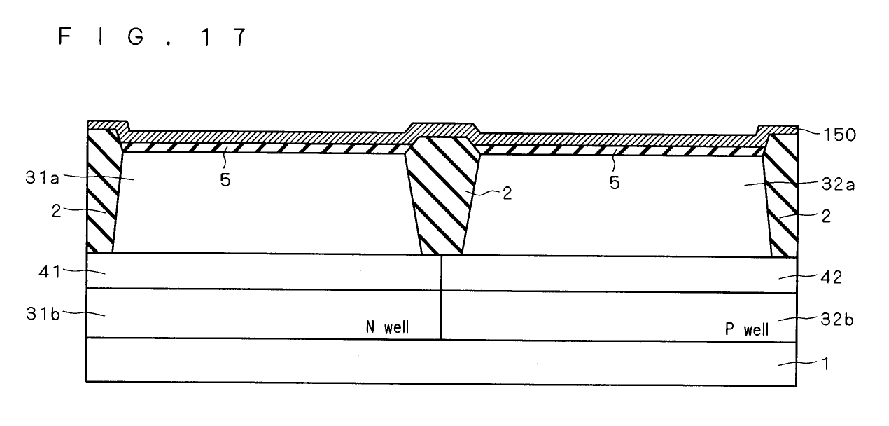

FIG. 16 is a cross-sectional view showing the structure of CMOS transistor 502 concerning this embodiment. CMOS transistor 502 is provided with PMOS transistor QP and NMOS transistor QN like Embodiment 1.

The structure except for transistors QP and QN (especially structure except for gate electrode GP and GN) is the same as that of CMOS transistor 501 (FIG. 1) explained by Embodiment 1 as it will be explained below. Therefore, explanation of structure that is common between Embodiment 1 and Embodiment 2 is omitted by this embodiment. In CMOS transistor 502, the same reference is attached about the same member as the member which forms CMOS transistor 501.

First, the structure of PMOS transistor QP concerning this embodiment is explained.

PMOS transistor QP has gate insulating film (it can be grasped as a first gate insulating film) 5 between gate electrode GP, and the channel region of N type well 31a. As gate insulating film 5 here, except for silicon oxide or silicon oxynitride, hafnium oxides with a high dielectric constant, such as hafnium oxide (HfO₂), hafnium oxynitride (HfON), hafnium silicate (HfxSiyOz), hafnium silicon oxynitride (HfSiON), hafnium aluminate (HfxAlyOz), hafnium aluminum oxynitride (HfAlON), are employable.

Gate electrode GP includes first metal layer 150, second metal layer 151, third metal layer 152, polycrystalline silicon layer (it can be grasped as a third semiconductor layer) 63, and silicide layer 11 sequentially from the gate insulating film 5 side.

Here, first metal layer 150 stands face to face against the channel region formed in N type well 31a via gate insulating film 5. That is, the first metal layer 150 concerned mainly determines the work function of gate electrode GP which forms PMOS transistor QP. Therefore, the material which has a work function suitable for operation of the PMOS transistor QP concerned turns into material of first metal layer 150 (that is, the material is chosen from a viewpoint of a work function that first metal layer 150 was suitable for PMOS transistor QP).

Third metal layer 152 can suppress more that substances, such as an impurity, silicon, etc. from polycrystalline silicon layer 63, are diffused in the direction in which gate insulating film 5 is formed. That is, third metal layer 152 has a diffusion suppression effect of the above-mentioned substance higher than first metal layer 150 (therefore, as for third metal layer 152, the material is chosen from a viewpoint of the above-mentioned diffusion suppression effect).

The function differs between first metal layer 150 and third metal layer 152 as the above shows. That is, first metal layer 150 mainly has the work which determines the work function of gate electrode GP of PMOS transistor QP. On the other hand, third metal layer 152 mainly has the work which suppresses the diffusion of substances, such as an impurity and silicon, from polycrystalline silicon layer 63. And when forming the first and third metal layer 150,152, the material and the manufacture conditions which specialized in the function concerned are chosen.

In PMOS transistor QP, formation of second metal layer 151 is also omissible. However, when fourth metal layer 151 which forms gate electrode GN of NMOS transistor QN is formed, second metal layer 151 is simultaneously formed, as it will mention later. Here, in PMOS transistor QP, in omitting formation of second metal layer 151, the step which removes separately the second metal layer 151 concerned formed in PMOS transistor QP is needed. In order to abolish the step which removes the second metal layer 151 concerned separately and to aim at simplification of a manufacturing process, in gate electrode GP of PMOS transistor QP, second metal layer 151 is formed as it is.

The threshold voltage of gate electrode GP is determined by first metal layer 150, second metal layer 151, third metal layer 152, and polycrystalline silicon layer 63 in PMOS transistor QP.

Next, the structure of NMOS transistor QN concerning this embodiment is explained.

NMOS transistor QN has gate insulating film (it can be grasped as a second gate insulating film) 5 between gate electrode GN, and the channel region of P type well 32a. Besides silicon oxide or silicon oxynitride as gate insulating film 5, hafnium oxides with high dielectric constant, such as hafnium oxide (HfO₂), hafnium oxynitride (HfON), hafnium silicate (HfxSiyOz), hafnium silicon oxynitride (HfSiON), hafnium aluminate (HfxAlyOz), and hafnium aluminum oxynitride (HfAlON), are employable.

Gate electrode GN includes fourth metal layer 151, fifth metal layer 152, polycrystalline silicon layer (it can be grasped as a fourth semiconductor layer) 63, and silicide layer 11 sequentially from the gate insulating film 5 side.

Here, fourth metal layer 151 stands face to face against the channel region formed in P type well 32a via gate insulating film 5. That is, the fourth metal layer 151 concerned mainly determines the work function of gate electrode GN of NMOS transistor QN. Therefore, the material which has a work function suitable for operation of NMOS transistor QN concerned turns into material of fourth metal layer 151 (that is, the material is chosen from a viewpoint of a work function that fourth metal layer 151 is suitable for NMOS transistor QN).

Fifth metal layer 152 can suppress more that substances, such as an impurity, silicon, etc. from polycrystalline silicon layer 63, are diffused in the direction in which gate insulating film 5 is formed. That is, fifth metal layer 152 has a diffusion suppression effect of the above-mentioned substance higher than first metal layer 150, for example (therefore, as for fifth metal layer 152, the material is chosen from a viewpoint of the diffusion suppression effect of the above-mentioned substance).

The function differs between fourth metal layer 151 and fifth metal layer 152 as the above shows. That is, fourth metal layer 151 mainly has the work which determines the work function of gate electrode GN of NMOS transistor QN. On the other hand, fifth metal layer 152 mainly has the work which suppresses diffusion of substances, such as an impurity, silicon, etc. from polycrystalline silicon layer 63. And when forming the fourth and fifth metal layer 151,152, the material and the manufacture conditions which specialized in the function concerned are chosen.

Second metal layer 151 and fourth metal layer 151 are formed at the same step as it will mention later. Therefore, both second metal layer 151 and fourth metal layer 151 have the same material (material, crystallinity, etc.) and the almost same (about the same) thickness. Third metal layer 152 and fifth metal layer 152 are formed at the same step. Therefore, both third metal layer 152 and fifth metal layer 152 have the same material (material, crystallinity, etc.) and the almost same (about the same) thickness.

In NMOS transistor QN, diffusion of the silicon to gate insulating film 5 direction etc. does not pose a problem from polycrystalline silicon layer 63 so much. Therefore, in NMOS transistor QN, formation of fifth metal layer 152 is also omissible. However, when third metal layer 152 which forms gate electrode GP of PMOS transistor QP is formed, fifth metal layer 152 is simultaneously formed, as it will mention later. Here, in NMOS transistor QN, in omitting formation of fifth metal layer 152, the step which removes separately the fifth metal layer 152 concerned formed in NMOS transistor QN is needed. In order to abolish the step which removes the fifth metal layer 152 concerned separately and to aim at simplification of a manufacturing process, in gate electrode GN of NMOS transistor QN, fifth metal layer 152 is formed as it is.

The threshold voltage of gate electrode GN is determined by fourth metal layer 151, fifth metal layer 152, and polycrystalline silicon layer 63 in NMOS transistor NQ.

When adopting polycrystalline silicon as a gate electrode in a CMOS transistor, the conductivity type of these gate electrodes is usually changed. It is because it is necessary to adjust mutual threshold voltage by the PMOS transistor and an NMOS transistor.

However, in this embodiment, polycrystalline silicon layer 63 of gate electrode GP and the channel region of PMOS transistor QP cannot be said to be confronting each other only via gate insulating film 5. Polycrystalline silicon layer 63 of gate electrode GN and the channel region of NMOS transistor QN cannot be said to be confronting each other only via gate insulating film 5. Therefore, the conductivity type of polycrystalline silicon layer 63 of gate electrode GP and GN does not determine the threshold voltage of transistors QP and QN promptly. Then, in this embodiment, the conductivity type of polycrystalline silicon layer 63 can be done in common also in any of gate electrode GP and GN, and an N type is adopted as the conductivity type concerned in this embodiment.

Of course, first metal layer 150 of gate electrode GP and a channel region confront each other only via gate insulating film 5. Therefore, it is desirable to adopt the metal which has a work function (work function of 4.8 eV or more) suitable for PMOS transistor QP as a metallic material of first metal layer 150.

Fourth metal layer 151 of gate electrode GN and a channel region confront each other only via gate insulating film 5. It is desirable to adopt the metal which has a work function (work function of 4.3 eV or less) suitable for NMOS transistor QN as a metallic material of fourth metal layer 151. It is because the device whose threshold voltage can also be small and which can drive PMOS transistor QP and NMOS transistor QN with low electric power becomes producible.

Here, as a metallic material which satisfies the requirements for metal layers 150-152, for example, titanium nitride (TiN), tungsten nitride (WN), nickel (Ni), rhenium (Re), iridium (Ir), platinum (Pt), ruthenium oxide (RuO2), iridium oxide (IrO2), and molybdenum nitride (MoN) can be mentioned.

Investigation which uses titanium nitride (TiN) as a metal gate electrode material is also advanced. However, since the work function is set to about 4.6 eV, as for the TiN film formed by the conventional sputtering technique, in an NMOS transistor and a PMOS transistor, threshold voltage Vₜₕ becomes high. However, a TiN film is formed as first metal layer 64 at the low temperature less than 450° C. with the thermal CVD method using TiCl₄ and NH₃. By this, the damage to gate insulating film 5 can be suppressed, and gate leakage current can be reduced, and a work function of 4.8 eV or more suitable for PMOS transistor QP can be acquired.

In the case of structure concerning Embodiment 1, in gate electrode GP of PMOS transistor QP, the portion in contact with gate insulating film 5 is made into first metal layer 64. Above Fermi level pinning, gate-electrode depletion-ization, etc. which may be generated in a PMOS transistor are solvable. However, the portion which contacts gate insulating film 5 in gate electrode GN in NMOS transistor QN was polycrystalline silicon layer 63. Therefore, there was a case where the problem of the depletion layer formation in the gate electrode GN concerned would become remarkable depending on the specification (that is, when gate insulating film 5 which forms NMOS transistor QN reduces thickness more).

So, in the case of this embodiment, in gate electrode GN of NMOS transistor QN, the portion in contact with gate insulating film 5 is made into fourth metal layer 151 as above-mentioned. Therefore, even if gate insulating film 5 which forms NMOS transistor QN reduces thickness, formation of the depletion layer in the above-mentioned gate electrode GN can be prevented. As mentioned above, the structure and the formation method of the fourth metal layer 151 concerned are selected so that the fourth metal layer concerned may have a proper work function from a viewpoint of operation of NMOS transistor QN.

In this embodiment, the portion which contacts gate insulating film 5 in gate electrode GP of PMOS transistor QP is made into first metal layer 150 like Embodiment 1. Therefore, each problem which may be generated in PMOS transistor QP, such as the above-mentioned Fermi level pinning, and gate-electrode depletion-izing, is solvable.

Gate electrode GP which forms PMOS transistor QP is formed from this embodiment by first metal layer 150, second metal layer 151, third metal layer 152, and polycrystalline silicon layer 63. Gate electrode GN which forms NMOS transistor QN is formed by fourth metal layer 151, fifth metal layer 152, and polycrystalline silicon layer 63.

Therefore, each metal layers 150-152 and polycrystalline silicon layer 63 can adjust (control) the threshold voltage of each MOS transistors QP and QN to a suitable value. That is, by the part for the number of layers of the metal layer to have increased from the case of the structure of Embodiment 1 in each gate electrode GP and GN, the threshold voltage of each MOS transistors QP and QN can be adjusted (controlled) with more sufficient accuracy (finely).

As mentioned above, second metal layer 151 in gate electrode GP and fifth metal layer 152 in gate electrode GN may be omitted. However, by having unabridged structure, as mentioned above, the excessive removal process of metal layer 151,152 can be skipped. As mentioned above, the threshold voltage of each MOS transistors QP and QN can be adjusted with more sufficient accuracy (finely).

In this embodiment, polycrystalline silicon layer 63 of gate electrode GP and the channel region of PMOS transistor QP cannot be said to be confronting each other only via gate insulating film 5. Therefore, the conductivity type of polycrystalline silicon layer 63 of the gate electrode GP concerned does not determine the threshold voltage of PMOS transistor QP promptly. Similarly, polycrystalline silicon layer 63 of gate electrode GN and the channel region of NMOS transistor QN cannot be said to be confronting each other only via gate insulating film 5. Therefore, the conductivity type of polycrystalline silicon layer 63 of the gate electrode GN concerned does not determine the threshold voltage of NMOS transistor QN promptly.

Therefore, polycrystalline silicon layer 63 of the same conductivity type as polycrystalline silicon layer 63 formed in NMOS transistor QN concerned can be formed on the above-mentioned third metal layer 152 according to the structure concerned, for example. That is, since it becomes unnecessary to introduce the impurity of a conductivity type which is different in each polycrystalline silicon layer 63, simplification of a manufacturing process can be aimed at.

In this embodiment, first metal layer 150 is formed on gate insulating film 5, and third metal layer 152 is formed in the first metal layer 150 upper part concerned. Therefore, the structure and the manufacturing process of the first metal layer 150 concerned can be chosen and determined so that first metal layer 150 may have a proper work function from a viewpoint of operation of PMOS transistor QP. On the other hand, the structure and the manufacturing process of the third metal layer 152 concerned can be chosen and determined so that third metal layer 152 may have a higher diffusion suppression effect of the above-mentioned substance.

Thus, in this embodiment, since production of each metal layer 150,152 concerned becomes easy by forming separately independently metal layer 150,152 which specialized in each above-mentioned function, the difficulty of a manufacturing process is avoidable. In PMOS transistor QP which is a transistor of the side where it becomes remarkable among CMOS transistors diffusing to the channel region of the impurity introduced into the polycrystalline silicon adopted in a gate electrode or silicon, change of the electrical property resulting from diffusion of the impurity concerned, silicon, etc. is avoidable.

When a hafnium oxide is adopted as gate insulating film 5 and polycrystalline silicon layer 63 of gate electrode GP contacts gate insulating film 5, it is easy to generate the problem of an interface state called the so-called Fermi level pinning. However, in this embodiment, since first metal layer 150 etc. contacts gate insulating film 5, this problem is also avoidable. Therefore, the present invention is preferred, when adopting a hafnium oxide as gate insulating film 5 and raising the dielectric constant.

In this embodiment, first metal layer 150 and third metal layer 152 can be formed with both titanium nitrides. It becomes possible to form first metal layer 150 which has a work function (4.8 eV or more) suitable for PMOS transistor QP, without giving a damage to gate insulating film 5, when titanium nitride is adopted as each metal layer 150,152. It becomes possible to form third metal layer 152 which can suppress more diffusion of silicon, an impurity, etc. from polycrystalline silicon layer 63. Since third metal layer 152 and fifth metal layer 152 are formed at the same step as above-mentioned, they have the same material and about the same thickness.

Fourth metal layer 151 (second metal layer 151 is also the same) needs to have a work function (4.3 eV or less) suitable for NMOS transistor QN. When the damage relief to gate insulating film 5 at the time of formation is taken into consideration, Hf, Zr, Al, Ti, Ta and Mo, such nitrides or silicon nitride, etc. is employable as fourth metal layer 151.

In this embodiment, polycrystalline silicon layer 63 is adopted on third metal layer 152 in gate electrode GP as above-mentioned. Hereby, thickness of each metal layers 150-152 can be made thin. In gate electrode GN, polycrystalline silicon layer 63 is adopted on fifth metal layer 152. Hereby, thickness of each metal layer 151,152 can be made thin. Therefore, when patterning each polycrystalline silicon layer 63 in gate electrode GP and GN, each metal layers 150-152 concerned can also be patterned collectively, and manufacture becomes easy also from this viewpoint.

Next, the manufacturing method of the semiconductor device (CMOS transistor 502) which has a MOS structure concerning this embodiment is explained. Here, the step from FIG. 2 to FIG. 4 explained by Embodiment 1 is common also in this embodiment.

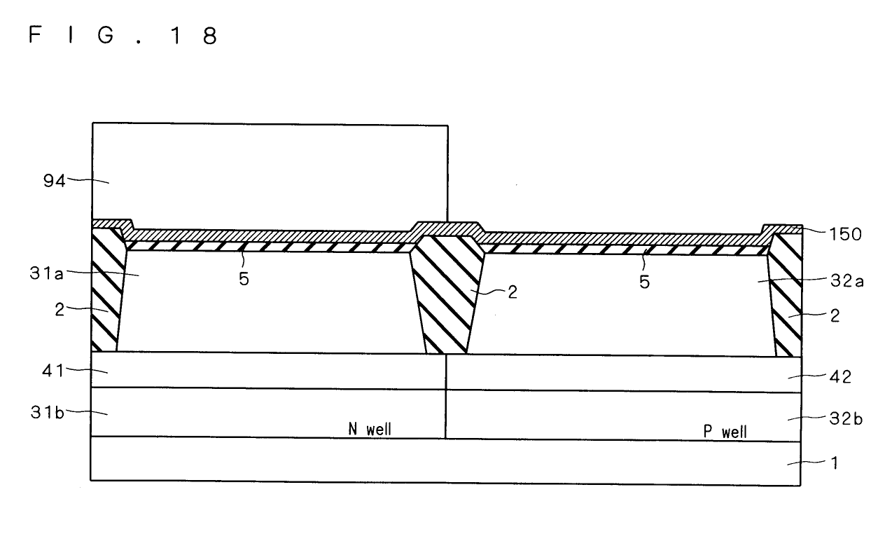

Now, with reference to FIG. 17, the whole surface exposed by the main surface side is covered after the step explained using FIG. 4, and metal layer 150 of the 1st layer is formed by predetermined thickness on gate insulating film 5. Here, metal layer 150 of the 1st layer concerned turns into first metal layer 150 in gate electrode GP of a finished product.

The titanium nitride (TiN) generated, for example by the CVD (Chemical Vapor Deposition) method is adopted as metal layer 150 of the 1st layer concerned. The ALD method (ALD: Atomic Layer Deposition) or the physical vapor deposition (sputtering) (PVD: Physical Vapor Deposition) of a low damage may be used except for a CVD method. It must be the method of not giving a damage to gate insulating film 5 and not degrading the characteristics of gate insulating film 5.

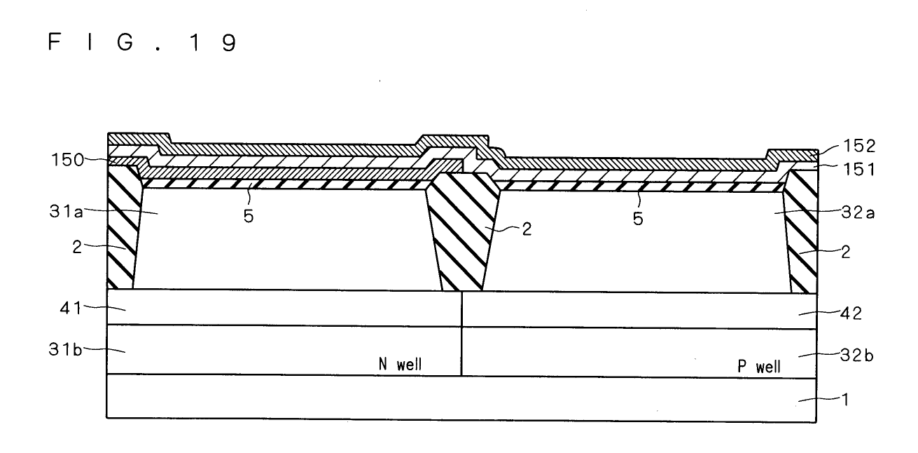

Now, with reference to FIG. 18, above N type well 31a, photoresist 94 is formed on metal layer 150 of the 1st layer. And metal layer 150 of the 1st layer is patterned by using the photoresist 94 concerned as a mask. Hereby, metal layer 150 of the 1st layer is removed in the upper part of P type well 32a (that is, gate insulating film 5 is exposed in the region concerned), and is left behind in the upper part of N type well 31a. Photoresist 94 is removed after that.

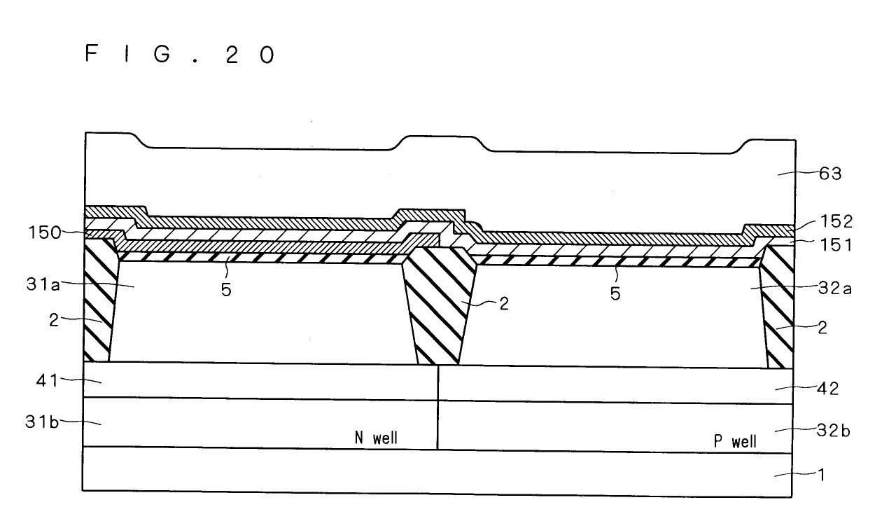

With reference to FIG. 19, the whole surface exposed by the main surface side is covered, and metal layer 151 of the 2nd layer is formed by predetermined thickness. Hereby, in the upper part of N type well 31a, metal layer 151 of the 2nd layer is formed on metal layer 150 of the 1st layer, and metal layer 151 of the 2nd layer is formed on gate insulating film 5 in the upper part of P type well 32a. With reference to FIG. 19, metal layer 152 of the 3rd layer is formed by predetermined thickness on the second metal layer 151 concerned.

Metal layer 151 of the 2nd layer concerned turns into second metal layer 151 in gate electrode GP of a finished product, and turns into fourth metal layer 151 in gate electrode GN of a finished product. Metal layer 152 of the 3rd layer concerned turns into third metal layer 152 in gate electrode GP of a finished product, and turns into fifth metal layer 152 in gate electrode GN of a finished product.

The titanium nitride (TiN) generated, for example by a CVD method is adopted as metal layer 150 of the 1st layer concerned. The tantalum nitride (TaN) generated, for example by a CVD method is adopted as metal layer 151 of the 2nd layer. The ALD method or the physical vapor deposition (sputtering) of a low damage may be used except for a CVD method. When forming metal layer 150 of the 1st layer, and metal layer 151 of the 2nd layer, it must be the method of not giving a damage to gate insulating film 5 and not degrading the characteristics of gate insulating film 5. On the other hand, in the case of formation of metal layer 152 of the 3rd layer, since there is metal layer 150 of the 1st layer or metal layer 151 of the 2nd layer, the technique of giving a damage somewhat is also satisfactory, and the sputtering technique with few impurities is good. Titanium nitride is employable as metal layer 152 of the 3rd layer.

In order to suppress diffusion of silicon, an impurity, etc. from polycrystalline silicon layer 63 later formed on third metal layer 152, to form metal layer 152 of the 3rd layer at a temperature (for example, more than 500° C.) higher than the forming temperature (for example, about 100° C.) of metal layer 150 of the 1st layer is desired.

In order to etch first metal layer 150-third metal layer 152 along with etching of polycrystalline silicon layer 63 as it will mention later, the thinner side of the total of the thickness of first metal layer 150-third metal layer 152 is desirable. As mentioned above, first metal layer 150 needs to have a suitable work function of PMOS transistor QP, and is considered that about 2 nm-5 nm thickness is required for metal layer 150 of the 1st layer from this request. As mentioned above, fourth metal layer 151 needs to have a work function with suitable NMOS transistor QN, and is considered that about 2 nm-5 nm thickness is required for metal layer 151 of the 4th layer from this request. Third metal layer 152 needs to prevent diffusion of silicon appropriately, and is considered that thickness of 5 nm or more (for example, about 5 nm-10 nm) is required for metal layer 152 of the 3rd layer from this request.

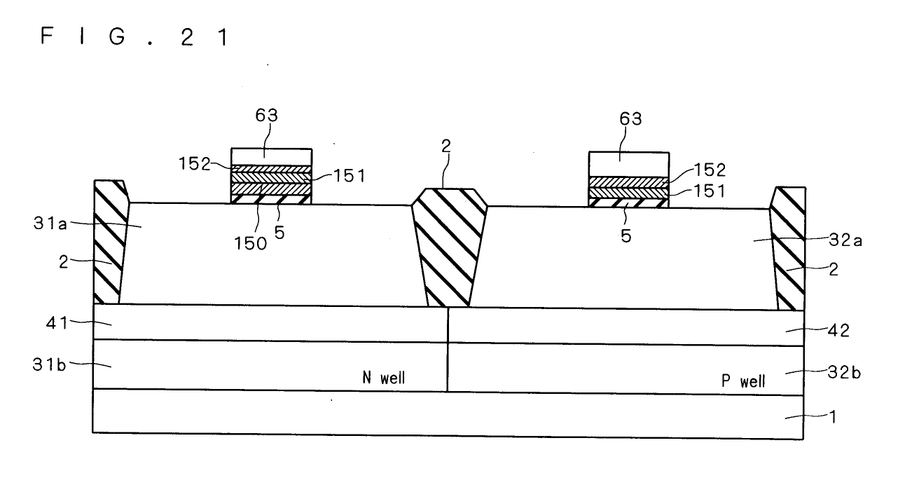

With reference to FIG. 20, the whole surface exposed by the main surface side is covered, and polycrystalline silicon layer 63 is formed. In the upper part of N type well 31a, the laminated structure of gate insulating film 5, metal layer 150 of the 1st layer, metal layer 151 of the 2nd layer, metal layer 152 of the 3rd layer, and polycrystalline silicon layer 63 is formed. On the other hand, in the upper part of P type well 32a, the laminated structure of gate insulating film 5, metal layer 151 of the 2nd layer, metal layer 152 of the 3rd layer, and polycrystalline silicon layer 63 is formed. In order to use the conductivity type of polycrystalline silicon layer 63 as an N type, it is desirable to form polycrystalline silicon layer 63, introducing the impurity (for example, phosphorus) of an N type.

After forming polycrystalline silicon layer 63, also by implanting the impurity of an N type from the front surface, the conductivity type of polycrystalline silicon layer 63 can be used as an N type. However, the side which forms polycrystalline silicon layer 63 introducing the impurity of an N type can reduce the generation of the depletion layer at the side of gate insulating film 5 of gate electrode GN rather than the case where ion implantation is performed to near the gate insulating film 5. The thickness and impurity concentration of polycrystalline silicon layer 63 are set, for example as 100 nm and 10²⁰cm⁻³, respectively.

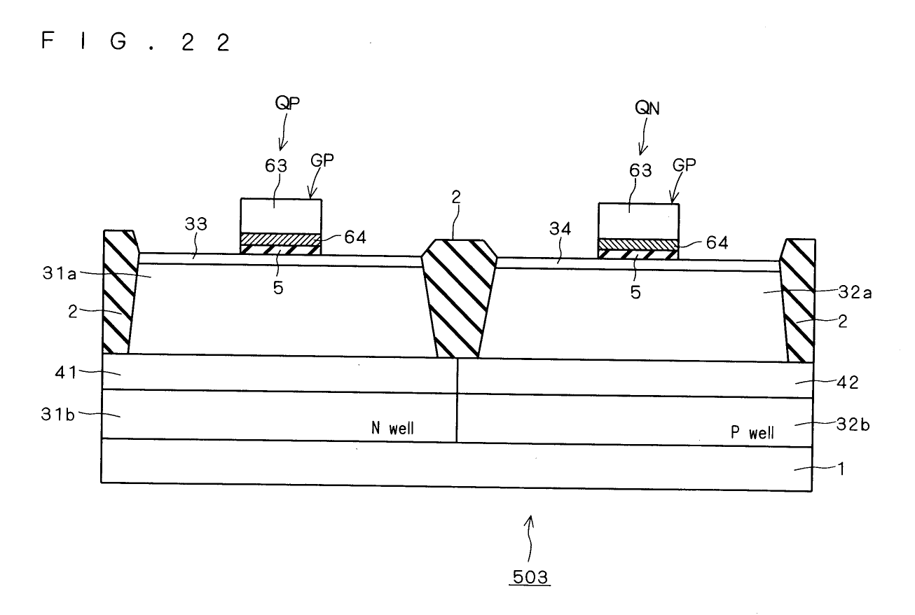

With reference to FIG. 21, well-known photolithography technology is adopted and polycrystalline silicon layer 63 and gate insulating film 5 are patterned. At the step which etches polycrystalline silicon layer 63, metal layer 150 of the 1st layer, metal layer 151 of the 2nd layer, and metal layer 152 of the 3rd layer can also be collectively etched in the formation area of PMOS transistor QP. In the formation area of NMOS transistor QN, metal layer 151 of the 2nd layer and metal layer 152 of the 3rd layer can also be collectively etched at the step which etches polycrystalline silicon layer 63.

By the etching processing concerned, first metal layer 150, second metal layer 151, and third metal layer 152 are formed in the formation area of PMOS transistor QP, and fourth metal layer 151 and fifth metal layer 152 are formed in the formation area of NMOS transistor QN.

When etching the polycrystalline silicon layer adopted as a gate electrode, usually the amount of over-etchings is set to about 1/10 of the thickness of a polycrystalline silicon layer. At this embodiment, polycrystalline silicon layer 63 is formed at the same step as both the upper part of P type well 32a, and the upper part of N type well 31a. Therefore, by forming metal layer 150 (it can be grasped as a first metal layer) of the 1st layer at the thickness which becomes 1/10 or less of the total of the thickness of polycrystalline silicon layer 63 (it can be grasped as the thickness of a third semiconductor layer or a fourth semiconductor layer), the thickness of metal layer 152 of the 3rd layer (it can be grasped as the thickness of a third metal layer or a fifth metal layer), and the thickness of metal layer 151 (it can be grasped as the thickness of a second metal layer or a fourth metal layer) of the 2nd layer (that is, by making the thickness of metal layer 150 of the 1st layer below the amount of over-etchings at the time of patterning polycrystalline silicon layer 63, etc.), the etching step in the patterning case of gate electrode GN and GP can be simplified.

Since the subsequent step is equivalent to the contents explained using FIG. 9 through FIG. 12, etc., explanation here is omitted. CMOS transistor 502 shown in FIG. 16 is obtained by the above.

As mentioned above, in order to etch each metal layers 150-152 along with etching of polycrystalline silicon layer 63, the thinner side of the total of the thickness of each metal layers 150-152 is desirable. However, first metal layer 150 and fourth metal layer 151 need to have a suitable work function, and are considered that thickness of 2 nm or more is required from this request. Third metal layer 152 needs to prevent diffusion of silicon appropriately, and is considered that thickness of 5 nm or more is required from this request.

With an above-mentioned structure, when the further adjustment of threshold voltage (Vₜₕ) is required, halogen ion (for example, fluorine ion) is moderately implanted into the front surface of N type well 31a on which gate electrode GP is formed. What is necessary is just to implant N₂ (nitrogen ion) moderately into the front surface of P type well 32a on which gate electrode GN is formed. For example, each ion implantation for the above-mentioned threshold voltage adjustment can be performed on the conditions that the concentration of fluorine ion is about 1˜3×10¹⁵/cm² and ion acceleration voltage is about 7 keV. The concentration of N₂ ion is about 0.5˜2×10¹⁵/cm² and it can carry out on the conditions whose ion acceleration voltage is about 22 keV.

There is the method of producing a TiN film with forming temperature (for example, more than 500° C.) higher than the forming temperature of first metal layer 150 as a method of forming third metal layer 152 which has diffusion suppression effects of such as silicon, as above-mentioned. When third metal layer 152 is formed with the comparatively high forming temperature concerned, as FIG. 15 showed, orientation of the formed TiN film is done to the surface (200). It turns out that the TiN film which did orientation to the surface (200). has a diffusion suppression effect of the above-mentioned silicon when putting in another way.

### Embodiment 3

In Embodiment 1 and 2, in order to adjust threshold voltage (Vₜₕ) further, it described implanting a predetermined impurity into the substrate main surface of CMOS transistor 501,502 illustrated to FIG. 1 and 16. For example, in order to adjust the threshold voltage of PMOS transistor QP, halogen ion (fluorine ion) is implanted into the front surface of N type well 31a. In order to adjust the threshold voltage of NMOS transistor QN, nitrogen ion is implanted into the front surface of P type well 32a.

However, when its attention is paid only to the viewpoint of adjustment of the threshold voltage (Vth) by implanting impurity ion into a substrate main surface, the structure (concretely structure of a gate electrode) of the target CMOS transistor does not have the need of restricting to FIG. 1 and 16. Therefore, in this embodiment, reference is made about the form which implanted predetermined impurity ion into the front surface of the main surface of a substrate in which the CMOS transistor which has gate electrode structure which is different in FIG. 1 and 16 was formed, and enabled adjustment of threshold voltage (Vₜₕ) with the ion implantation concerned.

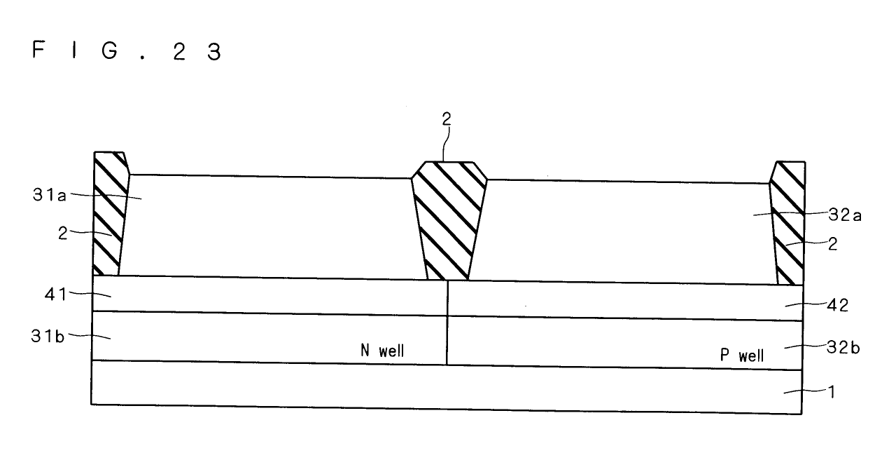

FIG. 22 is a cross-sectional view showing the structure of CMOS transistor 503 concerning this embodiment. Here, CMOS transistor 503 shown in FIG. 22 shows the structure in the middle of manufacture. Therefore, although illustration is omitted, in CMOS transistor 503 used as a finished product, a source/drain region, a sidewall, a spacer, an interlayer insulation film, the contact formed in the interlayer insulation film concerned, the wiring formed on the interlayer insulation film concerned, etc. will be formed.

Although CMOS transistor 503 shown in FIG. 22 is incomplete, it is provided with PMOS transistor QP and NMOS transistor QN. Here, PMOS transistor QP is formed in N type well 31 (here, it can be grasped that N type well 31a is a first semiconductor layer). On the other hand, NMOS transistor QN is formed in P type well 32 (here, it can be grasped that P type well 32a is a second semiconductor layer).

Both N type well 31 and P type well 32 are formed in one main surface (in FIG. 22, it is an upside) of semiconductor substrate 1. N type well 31a and P type well 32a are separated by element isolation insulator 2 (N type well 31b and P type well 32b are not separated by element isolation insulator 2 as FIG. 1 showed in addition). Each of semiconductor substrates 1, N type wells 31, and P type wells 32 adopts silicon as the main ingredients, for example. Unless it refuses in particular, silicon is employable similarly about other impurity layers. A silicon oxide is employable as element isolation insulator 2, for example.

In this embodiment, in the front surface of N type well 31a, first impurity implantation region 33 formed by implanting halogen ion (for example, fluorine ion) is formed as shown in FIG. 22. On the other hand, in the front surface of P type well 32a, second impurity implantation region 34 formed by implanting nitrogen ion is formed.

Here, first impurity implantation region 33 is formed by implanting fluorine ion on for example, the conditions whose ion acceleration voltage is about 7 keV in a concentration about 1˜3×10¹⁵/cm². Second impurity implantation region 34 is formed by implanting nitrogen ion on for example, the conditions whose ion acceleration voltage is about 22 keV in a concentration about 0.5˜2×10¹⁵/cm².

On N type well 31b formed on semiconductor substrate 1, N type element isolation diffusion layer 41 is formed. On the other hand, on P type well 32b formed on semiconductor substrate 1, P type element isolation diffusion layer 42 is formed.

PMOS transistor QP has gate electrode GP (it can be grasped as a first gate electrode and the gate electrode in the middle of manufacture is illustrated in FIG. 22). On the other hand, NMOS transistor QN has gate electrode GN (it can be grasped as a second gate electrode and gate electrode GN in the middle of manufacture is illustrated in FIG. 22). Like Embodiment 1, although it has a source/drain region, illustration is omitted by FIG. 22.

PMOS transistor QP has gate insulating film (it can be grasped as a first gate insulating film) 5 formed between gate electrode GP and the channel region of N type well 31a. On the other hand, NMOS transistor QN has gate insulating film (it can be grasped as a second gate insulating film) 5 formed between gate electrode GN and the channel region of P type well 32a.

Besides silicon oxide or silicon oxynitride as gate insulating film 5, hafnium oxides with high dielectric constant, such as hafnium oxide (HfO₂), hafnium oxynitride (HfON), hafnium silicate (HfxSiyOz), hafnium silicon oxynitride (HfSiON), hafnium aluminate (HfxAlyOz), and hafnium aluminum oxynitride (HfAlON), are employable.

Gate electrode GP includes first metal layer 64 and polycrystalline silicon layer (it can be grasped as a third semiconductor layer) 63 sequentially from the gate insulating film 5 side. Here, the first metal layer 64 concerned has some functions which suppress that silicon, an impurity, etc. are diffused in the gate insulating film 5 direction from polycrystalline silicon layer 63.

The threshold voltage of gate electrode GP is determined by first metal layer 64, polycrystalline silicon layer 63, the impurity concentration in first impurity implantation region 33, etc. in PMOS transistor QP.

Gate electrode GN includes second metal layer 64 and polycrystalline silicon layer (it can be grasped as a fourth semiconductor layer) 63 sequentially from the gate insulating film 5 side. The threshold voltage of gate electrode GN is determined by second metal layer 64, polycrystalline silicon layer 63, the impurity concentration in second impurity implantation region 34, etc. in NMOS transistor QN.

Second metal layer 64 and first metal layer 64 concerned are formed at the film formation step of the same metal layer as it may mention later. Therefore, as for first metal layer 64 and second metal layer 64, thickness is almost the same and it has the same material (material, crystallinity, etc.). Here as a metallic material of first metal layer 64 and the 2nd metal layer 64, for example, titanium nitride (TiN), tantalum nitride (TaN), tungsten nitride (WN), nickel (Ni), rhenium (Re), iridium (Ir), platinum (Pt), ruthenium oxide (RuO₂), iridium oxide (IrO₂), and molybdenum nitride (MoN) can be mentioned.

In CMOS transistor 503, it is necessary to change the conductivity type of polycrystalline silicon layer 63 which forms gate electrode GP, and the conductivity type of polycrystalline silicon layer 63 which forms gate electrode GN in this embodiment.

Thus, in this embodiment, the portion which contacts gate insulating film 5 in gate electrode GP of PMOS transistor QP which has the first threshold voltage is made into first metal layer 64. Therefore, each problem, such as gate-electrode depletion-izing etc. which may be generated in PMOS transistor QP, is solvable.

In this embodiment, second metal layer 64 is formed as a constituent element of gate electrode GN of NMOS transistor QN which has the second threshold voltage. Hereby, the formation of the depletion layer in gate electrode GN which originates in the thickness reduction of gate insulating film 5 which NMOS transistor QN has etc., and is generated can be prevented.

In this embodiment, not only first metal layer 64 and polycrystalline silicon layer 63 but the impurity concentration of the halogen ion in first impurity implantation region 33 can adjust the threshold voltage of gate electrode GP. Not only second metal layer 64 and polycrystalline silicon layer 63 but the impurity concentration of the nitrogen ion in second impurity implantation region 34 can adjust the threshold voltage of gate electrode GN.

When it summarizes, first metal layer 64 and second metal layer 64 mainly have the function to prevent formation of the depletion layer in gate electrode GP and GN. Adjustment (control) of threshold voltage (Vₜₕ) is mainly performed by formation of first impurity implantation region 33 and second impurity implantation region 34.

Next, the manufacturing method of the semiconductor device (CMOS transistor 503) which has a MOS structure concerning this embodiment is explained. Here, the step explained using FIG. 2 and FIG. 3 is the same as that of Embodiment 1. Therefore, detailed explanation here is omitted.

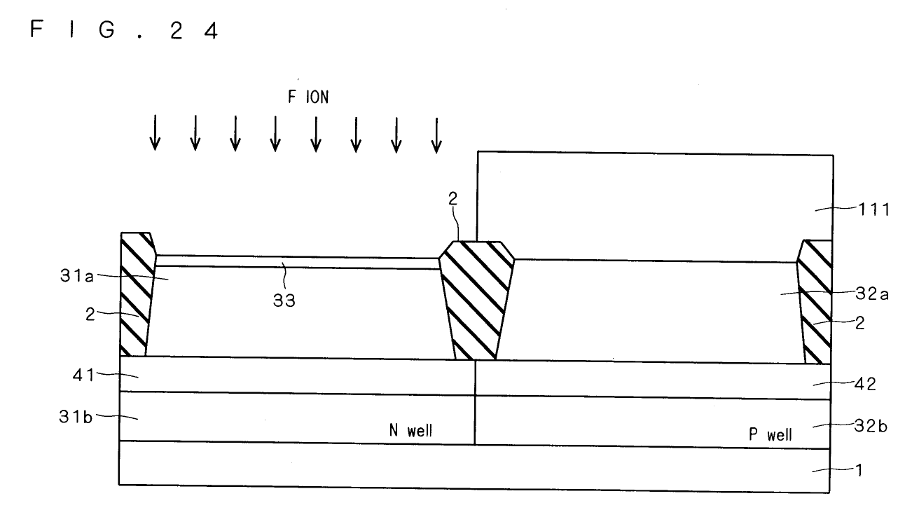

Oxide film 51 for implantation is removed after the step explained using FIG. 3. The state after the oxide film 51 removal for implantation concerned is shown in FIG. 23.

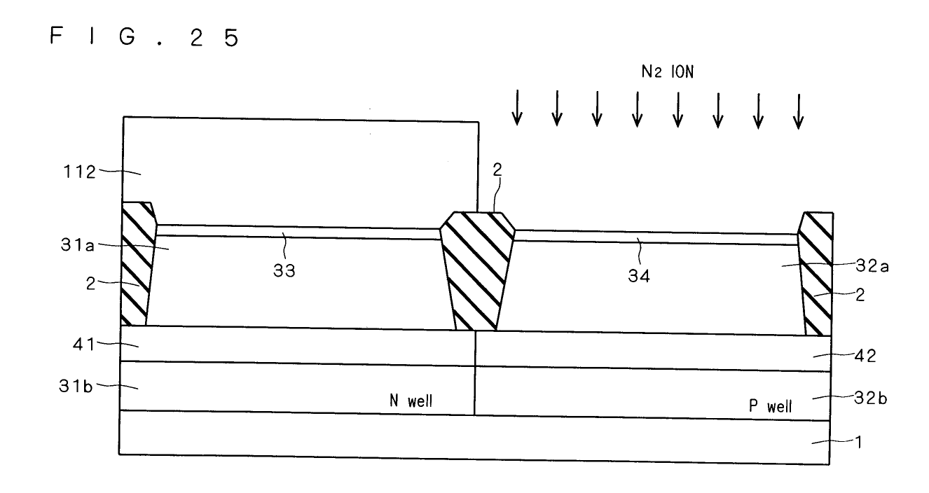

Now, as shown in FIG. 24, photoresist 111 is formed so that the region which forms NMOS transistor QN later may be covered. Here, in the step cross-sectional view after FIG. 23, PMOS transistor QP is formed in the left-hand side of element isolation insulator 2 shown in the center, and NMOS transistor QN is formed in right-hand side.

And as shown in FIG. 24, the photoresist 111 concerned is used as a mask and fluorine ion is implanted into the front surface of N type well 31a. Here, the implantation concentration and implantation energy of the fluorine ion concerned are as above-mentioned. By the fluorine ion implantation concerned, first impurity implantation region 33 is formed in the front surface of N type well 31a. Photoresist 111 is removed after that.

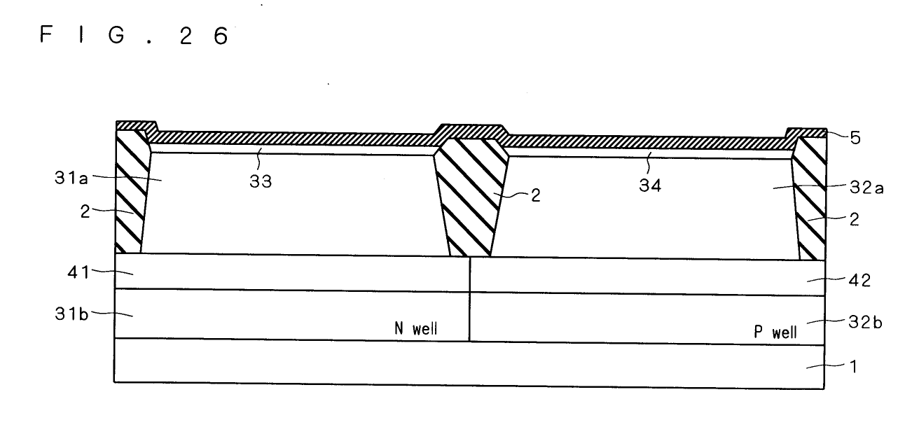

Next, as shown in FIG. 25, photoresist 112 is formed so that the region (that is, first impurity implantation region 33) which forms PMOS transistor QP later may be covered. And as shown in FIG. 25, the photoresist 112 concerned is used as a mask and nitrogen ion is implanted into the front surface of P type well 32a. Here, the implantation concentration and implantation energy of the nitrogen ion concerned are as above-mentioned. By the nitrogen ion implantation concerned, second impurity implantation region 34 is formed in the front surface of P type well 32a. Photoresist 112 is removed after that.

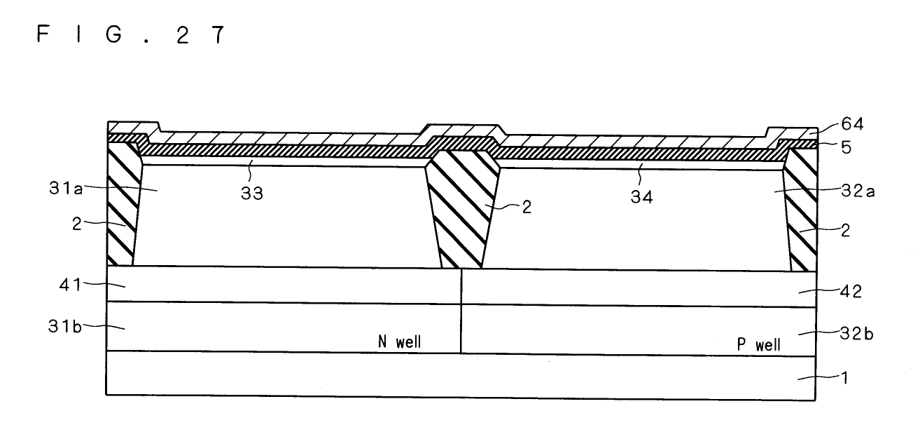

Next, as shown in FIG. 26, in both N type well 31a by which first impurity implantation region 33 was formed in the front surface, and P type well 32a by which second impurity implantation region 34 was formed in the front surface, gate insulating film 5 is formed on a main surface. Like previous statement as gate insulating film 5, hafnium oxides, such as hafnium silicon oxynitride (HfSiON), are employable.

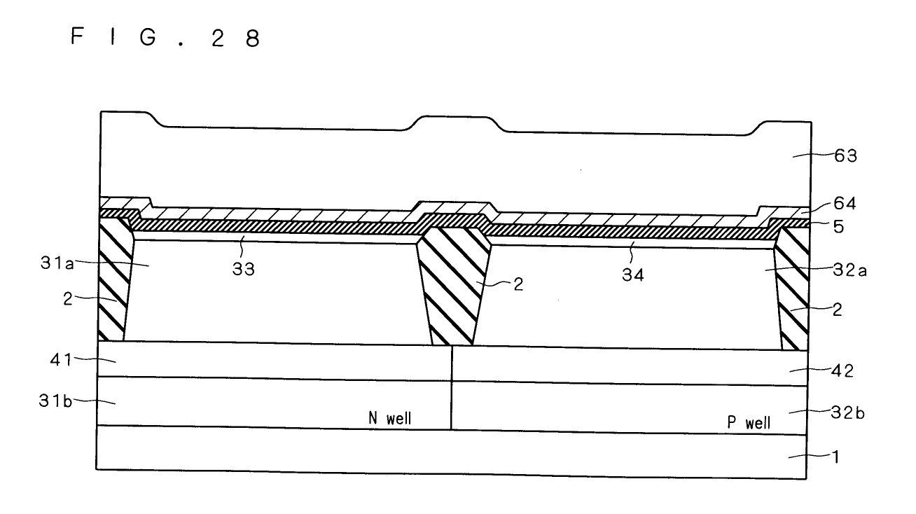

Next, as shown in FIG. 27, the whole surface exposed by the main surface side is covered, and metal layer 64 is formed by predetermined thickness (about 2 nm-5 nm) on gate insulating film 5. Here, in a finished product, the metal layer 64 concerned turns into first metal layer 64 which forms gate electrode GP, and turns into second metal layer 64 which forms gate electrode GN.

The titanium nitride (TiN) generated, for example by a CVD method is employable as metal layer 64. The ALD method, or the PVD method which is a low damage and has few impurities (sputtering) may be used except for a CVD method. It must be the method of not giving a damage to gate insulating film 5 and not degrading the characteristics of gate insulating film 5.

When metal layer 64 is formed by the sputtering technique of the low damage concerned, the damage which gate insulating film 5 receives can be suppressed to the minimum, and the impurity included in metal layer 64 also decreases (this contributes to the low resistance of metal layer 64). Formation of the depletion layer in gate electrode GP and GN which are completed can fully be suppressed, and the increase in the capacity of each MOS transistors QP and QN can also be expected.

As mentioned above, metal layer 64 turns into first metal layer 64 which forms gate electrode GP, and second metal layer 64 which forms gate electrode GN. And as above-mentioned, the first metal layer 64 concerned prevents formation of the depletion layer in gate electrode GP, and second metal layer 64 prevents formation of the depletion layer in gate electrode GN.

For the depletion layer formation prevention concerned, the side where the resistance of metal layer 64 formed at the above-mentioned step is lower is suitable. Therefore, the PVD method of a low damage with few impurities is the optimal.

Next, as shown in FIG. 28, the whole surface exposed by the main surface side is covered, and polycrystalline silicon layer 63 is formed on metal layer 64. The impurity of a P type is introduced into polycrystalline silicon layer 63 of the region in which PMOS transistor QP is formed (not shown), and the impurity of an N type is introduced into polycrystalline silicon layer 63 of the region in which NMOS transistor QN is formed (not shown).

Next, well-known photolithography technology is adopted and polycrystalline silicon layer 63, metal layer 64, and gate insulating film 5 are patterned. The structure shown in FIG. 22 is completed by the patterning concerned.

Subsequent formation methods, such as a source/drain region, a sidewall, a spacer, silicide, an interlayer insulation film, contact, and a wiring, are the same as that of Embodiment 1, and explanation here is omitted.

In Embodiment 1 through Embodiment 3, reference was made about polycrystalline silicon layer 63. However, an amorphous silicon layer may be adopted instead of the polycrystalline silicon layer 63 concerned. Amorphous silicon is easy in a micro fabrication as compared with polycrystalline silicon, and contributes to integration of a CMOS transistor.

The present invention is not limited to a CMOS transistor and can be applied to a plurality of MOS transistors which adopt a different threshold value. When it is a transistor which has a MOS structure, without being limited to a field-effect transistor, it is clear that it is applicable also to an insulated gate type bipolar transistor (IGBT).

What is claimed is:

1. A semiconductor device which has a MOS structure, comprising:
a first and a second semiconductor layer;
a first gate insulating film arranged over the first semiconductor layer;
a first gate electrode which has a first metal layer arranged over the first gate insulating film, a second metal layer arranged over the first metal layer, and a third semiconductor layer arranged over the second metal layer;
a second gate insulating film arranged over the second semiconductor layer; and
a second gate electrode which has a fourth semiconductor layer arranged over the second gate insulating film.

2. A semiconductor device which has a MOS structure according to claim 1, wherein
the second metal layer can suppress more diffusion of a substance from the third semiconductor layer to a direction of the first gate insulating film rather than the first metal layer.

3. A semiconductor device which has a MOS structure according to claim 1, wherein
the first gate insulating film and the second gate insulating film are hafnium oxides.

4. A semiconductor device which has a MOS structure according to claim 2, wherein
the first metal layer and the second metal layer are titanium nitrides.

5. A semiconductor device which has a MOS structure according to claim 4, wherein
the second metal layer is the titanium nitride which did orientation to a surface (200).

6. A semiconductor device which has a MOS structure according to claim 2, wherein a thickness of the second metal layer is 5 nm or more.

7. A semiconductor device which has a MOS structure according to claim 1, wherein
a total of a thickness of the first metal layer and a thickness of the second metal layer is 1/10 or less of a thickness of the third semiconductor layer.

8. A method of manufacturing a semiconductor device which has a MOS structure, comprising the steps of:
(a) forming a gate insulating film over a first semiconductor layer and a second semiconductor layer;
(b) forming a first metal layer over the gate insulating film;
(c) forming a second metal layer over the first metal layer;
(d) leaving the first metal layer and the second metal layer above the first semiconductor layer, and removing the first metal layer and the second metal layer from an upper part of the second semiconductor layer;
(e) forming a semiconductor layer for gate electrodes over the second metal layer and the second semiconductor layer; and
(f) forming a first gate electrode above the first semiconductor layer, and forming a second gate electrode above the second semiconductor layer by patterning the first metal layer, the second metal layer, and the semiconductor layer for gate electrodes.

9. A method of manufacturing a semiconductor device which has a MOS structure according to claim 8, wherein
the step (a) is a step which forms the gate insulating film which includes hafnium oxides.

10. A method of manufacturing a semiconductor device which has a MOS structure according to claim 8, wherein
the step (b) is a step which forms the first metal layer which includes titanium nitride; and
the step (c) is a step which forms the second metal layer which includes titanium nitride.

11. A method of manufacturing a semiconductor device which has a MOS structure according to claim 8, wherein
the step (b) is a step which forms the first metal layer by CVD method, ALD method, or PVD method; and
the step (c) is a step which forms the second metal layer by a PVD method.

12. A method of manufacturing a semiconductor device which has a MOS structure according to claim 8, wherein
the step (c) is a step which forms the second metal layer in a temperature higher than a forming temperature of the first metal layer.

13. A method of manufacturing a semiconductor device which has a MOS structure according to claim 12, wherein
the step (c) is a step which forms the second metal layer which includes titanium nitride on a temperature condition of more than 500° C.

14. A method of manufacturing a semiconductor device which has a MOS structure according to claim 8, wherein
the step (b) and the step (c) are steps which form the first metal layer and the second metal layer so that a total of a thickness of the first metal layer and a thickness of the second metal layer may become 1/10 or less of a thickness of the semiconductor layer for gate electrodes.

15. A semiconductor device which has a MOS structure, comprising:
a first and a second semiconductor layer;
a first gate insulating film arranged over the first semiconductor layer;
a first gate electrode which has a first metal layer arranged over the first gate insulating film, a second metal layer arranged over the first metal layer, a third metal layer arranged over the second metal layer, and a third semiconductor layer arranged over the third metal layer;
a second gate insulating film arranged over the second semiconductor layer; and
a second gate electrode which has a fourth metal layer arranged over the second gate insulating film, a fifth metal layer arranged over the fourth metal layer, and a fourth semiconductor layer arranged over the fifth metal layer;
wherein
the second metal layer and the fourth metal layer are layers of the same material and thickness; and
the third metal layer and the fifth metal layer are layers of the same material and thickness.

16. A semiconductor device which has a MOS structure according to claim 15, wherein
the third metal layer can suppress more diffusion of a substance from the third semiconductor layer to a direction of the first gate insulating film rather than the first metal layer.

17. A semiconductor device which has a MOS structure according to claim 15, wherein
the first gate insulating film and the second gate insulating film are hafnium oxides.

18. A semiconductor device which has a MOS structure according to claim 16, wherein
the first metal layer and the third metal layer are titanium nitrides.

19. A semiconductor device which has a MOS structure according to claim 18, wherein
the third metal layer and the fifth metal layer are the titanium nitrides which did orientation to a surface (200).

20. A semiconductor device which has a MOS structure according to claim 16, wherein
a thickness of the third metal layer and a thickness of the fifth metal layer are 5 nm or more.

21. A semiconductor device which has a MOS structure according to claim 15, wherein
a thickness of the first metal layer is 1/10 or less of a total of a thickness of the third semiconductor layer, a thickness of the third metal layer, and a thickness of the second metal layer.

22. A method of manufacturing a semiconductor device which has a MOS structure, comprising the steps of:
(a) forming a gate insulating film over a first semiconductor layer and a second semiconductor layer;
(b) forming a metal layer of a 1st layer over the gate insulating film;
(c) leaving the metal layer of the 1st layer above the first semiconductor layer, and removing the metal layer of the 1st layer from an upper part of the second semiconductor layer;
(d) forming a metal layer of a 2nd layer over the metal layer of the 1st layer, and the second semiconductor layer;
(e) forming a metal layer of a 3rd layer over the metal layer of the 2nd layer;
(f) forming a semiconductor layer for gate electrodes over the metal layer of the 3rd layer; and
(g) patterning the metal layer of the 1st layer, the metal layer of the 2nd layer, the metal layer of the 3rd layer, and the semiconductor layer for gate electrodes, forming a first gate electrode in the first semiconductor layer upper part, and forming a second gate electrode above the second semiconductor layer.

23. A method of manufacturing a semiconductor device which has a MOS structure according to claim 22, wherein
the step (a) is a step which forms the gate insulating film which includes hafnium oxides.

24. A method of manufacturing a semiconductor device which has a MOS structure according to claim 22, wherein
the step (b) is a step which forms a metal layer of a 1st layer which includes titanium nitride; and
the step (e) is a step which forms a metal layer of a 3rd layer which includes titanium nitride.

25. A method of manufacturing a semiconductor device which has a MOS structure according to claim 22, wherein
the step (b) and the step (d) are steps which form the metal layer of the 1st layer, and the metal layer of the 2nd layer by CVD method, ALD method, or PVD method; and
the step (e) is a step which forms the metal layer of the 3rd layer by a PVD method;

26. A method of manufacturing a semiconductor device which has a MOS structure according to claim 22, wherein
the step (e) is a step which forms the metal layer of the 3rd layer at a temperature higher than a forming temperature of the metal layer of the 1st layer.

27. A method of manufacturing a semiconductor device which has a MOS structure according to claim 26, wherein
the step (e) is a step which forms the metal layer of the 3rd layer which includes titanium nitride on a temperature condition of more than 500° C.

28. A method of manufacturing a semiconductor device which has a MOS structure according to claim 22, wherein
the step (b) is a step which forms the metal layer of the 1st layer which has a thickness which becomes 1/10 or less of a total of a thickness of the semiconductor layer for gate electrodes, the metal layer of the 2nd layer, and the metal layer of the 3rd layer.

29. A semiconductor device which has a MOS structure, comprising:
a first semiconductor layer which contained halogen in a front surface;
a second semiconductor layer which contained nitrogen in a front surface;
a first gate insulating film arranged over the first semiconductor layer;
a first gate electrode which has a first metal layer arranged over the first gate insulating film, and a third semiconductor layer arranged over the first metal layer;
a second gate insulating film arranged over the second semiconductor layer; and
a second gate electrode which has a second metal layer arranged over the second gate insulating film, and a fourth semiconductor layer arranged over the second metal layer;
wherein
the first metal layer and the second metal layer are layers of the same material and thickness.

30. A semiconductor device which has a MOS structure according to claim 29, wherein
the first gate insulating film and the second gate insulating film are hafnium oxides.

31. A method of manufacturing a semiconductor device which has a MOS structure, comprising the steps of:
(a) implanting halogen into a front surface of a first semiconductor layer;
(b) implanting nitrogen into a front surface of a second semiconductor layer;
(c) forming a gate insulating film over the first semiconductor layer and the second semiconductor layer;
(d) forming a metal layer over the gate insulating film;
(e) forming a semiconductor layer for gate electrodes over the metal layer; and
(f) patterning the metal layer and the semiconductor layer for gate electrodes, forming a first gate electrode above the first semiconductor layer, and forming a second gate electrode above the second semiconductor layer.

32. A method of manufacturing a semiconductor device which has a MOS structure according to claim 31, wherein
the step (c) is a step which forms the gate insulating film which includes hafnium oxides.

33. A method of manufacturing a semiconductor device which has a MOS structure according to claim 31, wherein
the step (d) is a step which forms the metal layer by PVD method.
